(19) United States
(12) Patent Application Publication
(10) Pub. No.: US 2026/0150468 A1
(43) Pub. Date: May 28, 2026

(54) MICRO LIGHT-EMITTING DISPLAY APPARATUS AND METHOD OF MANUFACTURING THE SAME

(71) Applicant: SAMSUNG ELECTRONICS CO., LTD., Suwon-si (KR)

(72) Inventors: Joohun Han, Suwon-si (KR); Youngtek Oh, Suwon-si (KR); Kyungwook Hwang, Suwon-si (KR); Sanghoon Song, Suwon-si (KR); Minchul Yu, Suwon-si (KR); Junsik Hwang, Suwon-si (KR)

(73) Assignee: SAMSUNG ELECTRONICS CO., LTD., Suwon-si (KR)

(21) Appl. No.: 19/400,444

(22) Filed: Nov. 25, 2025

(30) Foreign Application Priority Data
Nov. 26, 2024 (KR) 10-2024-0171452

(51) Int. Cl. H10H 29/80; H10H 29/01; H10H 29/32; H10H 29/34

(52) U.S. Cl. CPC H10H 29/842; H10H 29/011; H10H 29/012; H10H 29/034; H10H 29/32; H10H 29/34; H10H 29/8321; H10H 29/962

(57) ABSTRACT

Provided is a micro light-emitting display apparatus including a light-emitting stack structure configured to emit light through an upper surface of the light-emitting stack structure, the light-emitting stack structure including a first light-emitting element configured to emit light of a first wavelength and a second light-emitting element configured to emit light of a second wavelength, and a passivation layer on at least the upper surface of the light-emitting stack structure, wherein the passivation layer includes a first passivation region including a first material configured to transmit the light of the first wavelength external to the micro light-emitting display apparatus, and a second passivation region including a second material, different from the first material, configured to transmit the light of the second wavelength external to the micro light-emitting display apparatus, the second passivation region being on a same plane as the first passivation region.

### CROSS-REFERENCE TO RELATED APPLICATION

This application claims priority to Korean Patent Application No. 10-2024-0171452, filed on Nov. 26, 2024, in the Korean Intellectual Property Office, the disclosure of which is incorporated by reference herein in its entirety.

### BACKGROUND

### 1. Field

Embodiments of the present disclosure relate to a micro light-emitting display apparatus displaying color images and a method of manufacturing the same.

### 2. Description of the Related Art

Liquid crystal displays (LCDs) and organic light-emitting diode (OLED) displays are widely used as display apparatuses. In addition, technology for manufacturing relatively high-resolution display apparatuses using micro LEDs has recently been in the spotlight. LEDs have the advantages of relatively low power consumption and being eco-friendly. Because of these advantages, industrial demand for LEDs is increasing.

LED displays that directly use micro LEDs as pixels are being developed and commercialized.

LED display pixels may be designed in various ways, and recently, various technologies to vertically stack micro LEDs (R-LEDs) that emit red light (R), micro LEDs (G-LEDs) that emit green light (G), and micro LEDs (B-LEDs) that emit blue light (B) have been introduced.

### SUMMARY

One or more embodiments provide a micro light-emitting display apparatus.

One or more embodiments also provide a method of manufacturing a micro light-emitting display apparatus.

Additional aspects will be set forth in part in the description which follows and, in part, will be apparent from the description, or may be learned by practice of one or more embodiments.

According to an aspect of one or more embodiments, there is provided a micro light-emitting display apparatus including a light-emitting stack structure configured to emit light through an upper surface of the light-emitting stack structure, the light-emitting stack structure including a first light-emitting element configured to emit light of a first wavelength and a second light-emitting element configured to emit light of a second wavelength, and a passivation layer on at least the upper surface of the light-emitting stack structure, wherein the passivation layer includes a first passivation region including a first material configured to transmit the light of the first wavelength external to the micro light-emitting display apparatus, and a second passivation region including a second material, different from the first material, configured to transmit the light of the second wavelength external to the micro light-emitting display apparatus, the second passivation region being on a same plane as the first passivation region.

The first passivation region may include a first upper passivation region on a first partial region of the upper surface of the light-emitting stack structure, and the second passivation region may include a second upper passivation region on a second partial region of the upper surface of the light-emitting stack structure.

An end portion of a boundary part of the first upper passivation region and an end portion of a boundary part of the second upper passivation region opposite to each other may contact each other.

A thickness of the boundary part of the first upper passivation region may be greater than thicknesses of parts of the first upper passivation region other than the boundary part of the first upper passivation region and the second upper passivation region.

An end portion of the first upper passivation region and an end portion of the second upper passivation region opposite to each other may be spaced apart from each other.

A gap between the first upper passivation region and the second upper passivation region may correspond to a thickness of the first upper passivation region or a thickness of the second upper passivation regions.

The first passivation region may include a first side passivation region on a first partial region of a side surface of the light-emitting stack structure, and the second passivation region may include a second side passivation region on a second partial region of the side surface of the light-emitting stack structure.

The first side passivation region may be on a side surface of the first light-emitting element, and the second side passivation region may be on a side surface of the second light-emitting element.

The light-emitting stack structure may further include a first upper via hole extending downward from the upper surface of the light-emitting stack structure such that a first upper electrode is electrically connected to the first light-emitting element, and a second upper via hole extending downward from the upper surface of the light-emitting stack structure such that a second upper electrode is electrically connected to the second light-emitting element.

The first passivation region may include a first hole passivation region between an inner surface of the first upper via hole and the first upper electrode, and the second passivation region may include a second hole passivation region between an inner surface of the second upper via hole and the second upper electrode.

The light of the first wavelength may include a red light wavelength, and the first material may include at least one of SiO₂, AlN, AlON, Ta₂O₅, SiN, Al₂O₃, ZrO₂, or HfO₂.

The light of the second wavelength may include a blue light wavelength, and the second material may include at least one of SiO₂, AlN, AlON, Ta₂O₅, SiN, Al₂O₃, ZrO₂, or HfO₂.

The light-emitting stack structure may further include a third light-emitting element between the first light-emitting element and the second light-emitting element, the third light-emitting element being configured to emit light of a third wavelength different from the first wavelength and the second wavelength.

The passivation layer may further include a third passivation region including a third material different from the first material and the second material and configured to transmit the light of the third wavelength external to the micro light-emitting display apparatus, and the third passivation region may be on the same plane as the first passivation region and the second passivation region.

According to another aspect of one or more embodiments, there is provided an electronic device including a micro light-emitting display apparatus, and at least one processor configured to control the micro light-emitting display apparatus, wherein the micro light-emitting display apparatus includes a light-emitting stack structure configured to emit light through an upper surface of the light-emitting stack structure, the light-emitting stack structure including a first light-emitting element configured to emit light of a first wavelength and a second light-emitting element configured to emit light of a second wavelength, and a passivation layer on at least the upper surface of the light-emitting stack structure, wherein the passivation layer includes a first passivation region including a first material configured to transmit the light of the first wavelength external to the micro light-emitting display apparatus, and a second passivation region including a second material, different from the first material, configured to transmit the light of the second wavelength external to the micro light-emitting display apparatus, the second passivation region being on a same plane as the first passivation region.

According to still another aspect of one or more embodiments, there is provided a method of manufacturing a micro light-emitting display apparatus, the method including partially forming a first passivation region on a first region of a light-emitting stack structure that includes a first light-emitting element and a second light-emitting element, and forming a second passivation region on a second region of the light-emitting stack structure and on a same plane as the first passivation region, a material of the second passivation region being different from a material of the first passivation region.

The forming of the first passivation region may include forming the first passivation region on a first partial region of an upper surface of the light-emitting stack structure, and the forming of the second passivation region may include forming the second passivation region on a second partial region of the upper surface of the light-emitting stack structure.

The forming of the first passivation region may include forming the first passivation region on a first partial region of a side surface of the light-emitting stack structure, and the forming of the second passivation region may include forming the second passivation region on a second partial region of the side surface of the light-emitting stack structure.

The second passivation region may be adjacent to the first passivation region on an upper surface of the light-emitting stack structure.

A first material of the first passivation region may include at least one of SiO₂, AlN, AlON, Ta₂O₅, SiN, Al₂O₃, ZrO₂, or HfO₂, and a second material of the second passivation region may include at least one of SiO₂, AlN, AlON, Ta₂O₅, SiN, Al₂O₃, ZrO₂, or HfO₂.

### BRIEF DESCRIPTION OF DRAWINGS

The above and other aspects, features, and advantages of one or more embodiments will be more apparent from the following description taken in conjunction with the accompanying drawings, in which:

FIGS. 1A and 1B are respectively a perspective view and a plan view schematically illustrating an example of a micro light-emitting display apparatus according to one or more embodiments;

FIG. 2 is a cross-sectional view of the micro light-emitting display apparatus according to one or more embodiments taken along line II-II;

FIG. 3 is a cross-sectional view of the micro light-emitting display apparatus according to one or more embodiments taken along line III-III;

FIG. 4 is a diagram schematically illustrating another example of the micro light-emitting display apparatus according to one or more embodiments;

FIG. 5A is a diagram for explaining light of a first wavelength being emitted from a micro light-emitting display apparatus according to one or more embodiments, and FIG. 5B is a diagram for explaining light of a second wavelength being emitted from the micro light-emitting display apparatus according to one or more embodiments;

FIGS. 6A, 6B, and 6C are plan views illustrating various examples of a micro light-emitting display apparatus according to one or more embodiments;

FIGS. 7A and 7B are diagrams illustrating another example of a micro light-emitting display apparatus according to one or more embodiments;

FIGS. 8A and 8B are diagrams illustrating another example of a micro light-emitting display apparatus according to one or more embodiments;

FIG. 9 is a diagram illustrating an example of a part A that is a boundary between a plurality of passivation regions in the micro light-emitting display apparatus of FIG. 2;

FIGS. 10A, 10B, and 10C are diagrams illustrating other examples of the part A that is the boundary between the plurality of passivation regions in the micro light-emitting display apparatus of FIG. 2;

FIGS. 11A and 11B are diagrams illustrating another example of a micro light-emitting display apparatus according to one or more embodiments;

FIG. 12 is a diagram illustrating another example of a micro light-emitting display apparatus according to one or more embodiments;

FIG. 13 is a flowchart illustrating a method of manufacturing a micro light-emitting display apparatus, according to one or more embodiments;

FIGS. 14A, 14B, 14C, 14D, 14E, and 14F are diagrams illustrating an example of an operation of forming a first passivation region in the method of manufacturing the micro light-emitting display apparatus, according to one or more embodiments;

FIGS. 15A, 15B, 15C, 15D, and 15E are diagrams illustrating an example of an operation of forming a second passivation region in the method of manufacturing the micro light-emitting display apparatus, according to one or more embodiments;

FIG. 16 is a flowchart illustrating a method of manufacturing a micro light-emitting display apparatus, according to one or more embodiments;

FIGS. 17A, 17B, 17C, 17D, 17E, and 17F are an operation for explaining an example of an operation of forming a first hole passivation region in the method of manufacturing the micro light-emitting display apparatus, according to one or more embodiments;

FIGS. 18A, 18B, 18C, 18D, and 18E are diagrams for explaining an example of an operation of forming a second hole passivation region in the method of manufacturing the micro light-emitting display apparatus, according to one or more embodiments;

FIG. 19 is a block diagram of an electronic device including a display apparatus according to one or more embodiments;

FIG. 20 is a diagram illustrating an example in which a display apparatus according to one or more embodiments is applied to a mobile device;

FIG. 21 is a diagram illustrating an example in which a display apparatus according to one or more embodiments is applied to a vehicle;

FIG. 22 is a diagram illustrating an example in which a display apparatus according to one or more embodiments is applied to augmented reality glasses or virtual reality glasses;

FIG. 23 is a diagram illustrating an example in which a display apparatus according to one or more embodiments is applied to signage; and

FIG. 24 is a diagram illustrating an example in which a display apparatus according to one or more embodiments is applied to a wearable display.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, a micro light-emitting display apparatus and a method of manufacturing the same according to various embodiments are described in detail with reference to the accompanying drawings. In the drawings, like reference numerals in the drawings denote like elements, and sizes of components in the drawings may be exaggerated for clarity and convenience of explanation. While such terms as “first,” “second,” etc., may be used to describe various components, such components must not be limited to the above terms. The above terms are used only to distinguish one component from another.

An expression used in the singular encompasses the expression of the plural, unless it has a clearly different meaning in the context. When a portion “includes” an element, another element may be further included, rather than excluding the existence of the other element, unless otherwise described. Sizes or thicknesses of components in the drawings may be arbitrarily exaggerated for convenience of explanation. Further, when a certain material layer is described as being disposed on a substrate or another layer, the material layer may be in contact with the other layer, or there may be a third layer between the material layer and the other layer. In the following embodiments, materials constituting each layer are provided merely as an example, and other materials may also be used.

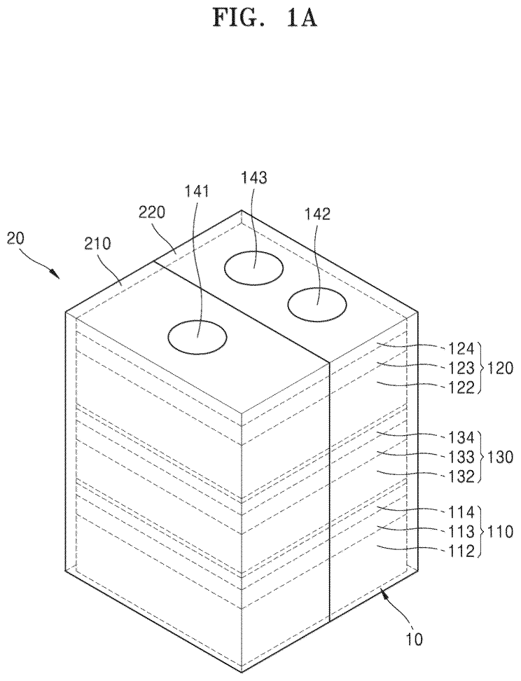

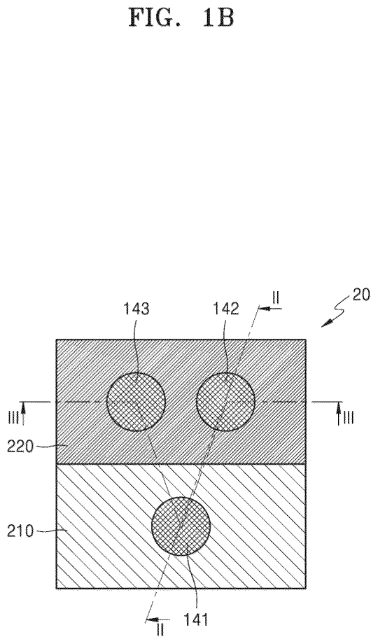

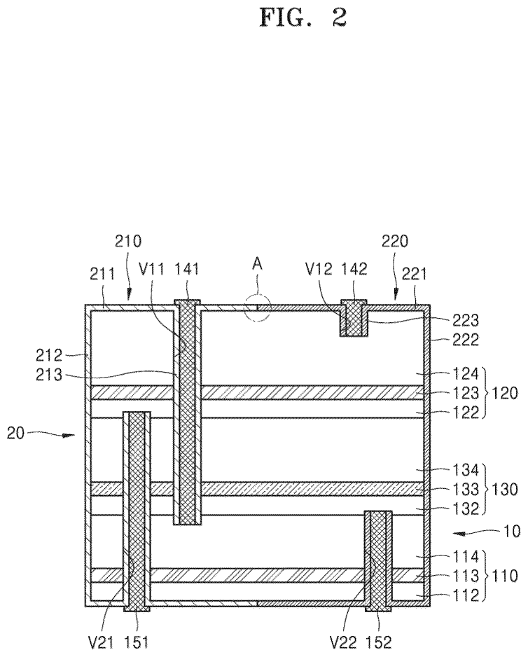

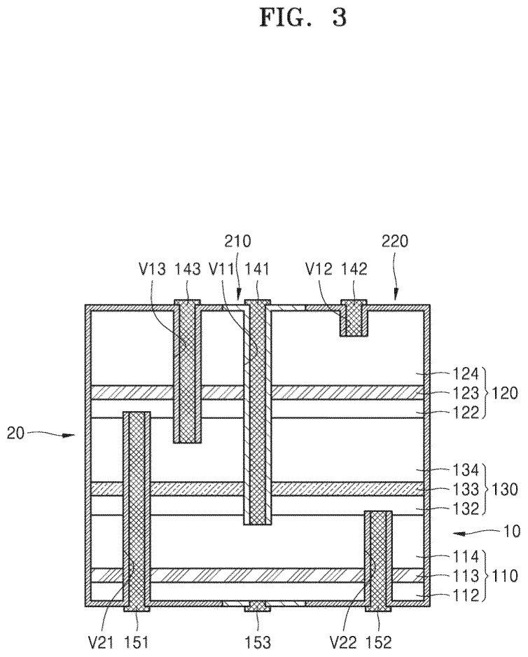

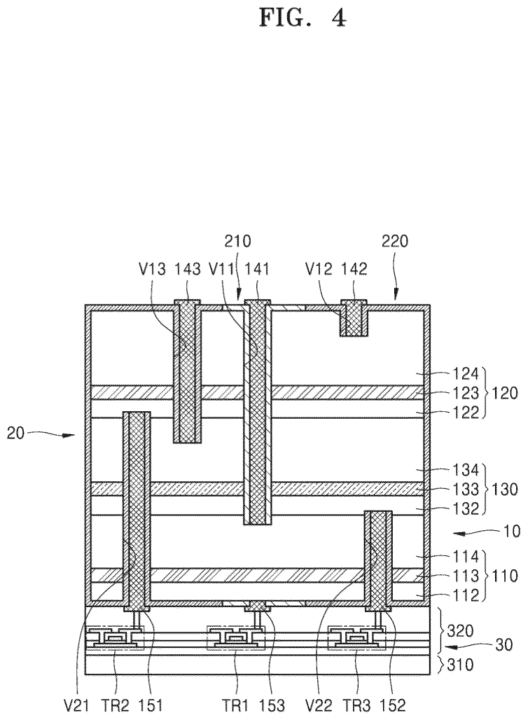

FIGS. 1A and 1B are a perspective view and a plan view schematically illustrating an example of a micro light-emitting display apparatus according to one or more embodiments. FIG. 2 is a cross-sectional view of the micro light-emitting display apparatus according to one or more embodiments taken along line II-II. FIG. 3 is a cross-sectional view of the micro light-emitting display apparatus according to one or more embodiments taken along line III-III. FIG. 4 is a diagram schematically illustrating another example of the micro light-emitting display apparatus according to one or more embodiments.

Referring to FIGS. 1A, 1B, 2 and 3, the micro light-emitting display apparatus may include a light-emitting stack structure 10 in which a plurality of light-emitting elements emitting light of different wavelengths are sequentially stacked. For example, the light-emitting stack structure 10 may include a first light-emitting element 110 and a second light-emitting element 120 that emit light of different wavelengths that are sequentially stacked. The light-emitting stack structure 10 may have a monolithically arranged structure. The light-emitting stack structure 10 may emit light through an upper surface thereof. Herein, “sequentially” represents the order of layers, and do not exclude the intervention of other layers between the layers.

The first light-emitting element 110 may include a first semiconductor layer 112, a first active layer 113 that emits light of a first wavelength, and a second semiconductor layer 114, which are sequentially stacked. The first light-emitting element 110 may have a micro-sized width. For example, the width of the first light-emitting element 110 may be in the range from about 0.1 μm to 100 μm.

The first semiconductor layer 112 may include a first type semiconductor. For example, the first semiconductor layer 112 may include a p-type semiconductor. As another example, the first semiconductor layer 112 may include an n-type semiconductor. The first semiconductor layer 112 may include a Group III-V based p-type semiconductor, for example, p-gallium nitride (p-GaN), p-indium gallium nitride (p-InGaN), p-aluminum indium gallium nitride (p-AlInGaN), or p-aluminum gallium indium phosphide (p-AlGaInP). The first semiconductor layer 112 may have a single-layer structure or a multi-layer structure.

The first active layer 113 may be provided on an upper surface of the first semiconductor layer 112. In the first active layer 113, electrons and holes may be combined to generate light. The first active layer 113 may include a material that emits light of the first wavelength, for example, red light. However, the first active layer 113 is not limited thereto. The first active layer 113 may have a multi-quantum well (MQW) structure or a single-quantum well (SQW) structure. The first active layer 113 may include a Group III-V semiconductor, for example, GaN, InGaN, AlInGaN, or AlGaInP.

The second semiconductor layer 114 may be provided on an upper surface of the first active layer 113. The second semiconductor layer 114 may include, for example, an n-type semiconductor. As another example, the second semiconductor layer 114 may include a p-type semiconductor. The second semiconductor layer 114 may include a Group III-V based n-type semiconductor, for example, n-GaN, n-InGaN, n-AlInGaN, or n-AlGaInP. The second semiconductor layer 114 may have a single-layer structure or a multi-layer structure.

The first light-emitting element 110 may generate light of the first wavelength when voltage is applied thereto and the first active layer 113 is activated. For example, the light of the first wavelength may include a red light wavelength, for example, light in a wavelength range of 630±20 nm. However, embodiments are not limited thereto.

The second light-emitting element 120 may be disposed on the first light-emitting element 110. For example, the second light-emitting element 120 may include a third semiconductor layer 122, a second active layer 123 that emits light of a second wavelength, and a fourth semiconductor layer 124, which are sequentially stacked.

The second light-emitting element 120 may have a micro-sized width. For example, the width of the second light-emitting element 120 may be in the range from 0.1 μm to 100 μm. The width of the second light-emitting element 120 may be the same as the width of the first light-emitting element 110. However, the width of the second light-emitting element 120 is not limited thereto, and may be smaller than the width of the first light-emitting element 110.

The third semiconductor layer 122 may include a first type semiconductor. For example, the third semiconductor layer 122 may include a p-type semiconductor. As another example, the third semiconductor layer 122 may include an n-type semiconductor. The third semiconductor layer 122 may include a Group III-V based p-type semiconductor, for example, p-GaN, p-InGaN, p-AlInGaN, or p-AlGaInP. The third semiconductor layer 122 may have a single-layer structure or a multi-layer structure. The third semiconductor layer 122 may include the same material as the first semiconductor layer 112. As another example, the third semiconductor layer 122 may include a material different from a material of the first semiconductor layer 112.

The second active layer 123 may be provided on an upper surface of the third semiconductor layer 122. The second active layer 123 may generate light of the second wavelength, and the second wavelength may be different from the first wavelength. For example, the light of the second wavelength may include a blue light wavelength, for example, light in a wavelength range of 460±20 nm. However, embodiments are not limited thereto.

The second active layer 123 may have a multi-quantum well (MQW) structure or a single quantum well (SQW) structure. The second active layer 123 may include a Group III-V semiconductor, for example, GaN, InGaN, AlInGaN, or AlGaInP. The second active layer 123 may include a material different from a material of the first active layer 123. Here, the different material may include not only cases in which constituent elements are different, but also cases in which constituent elements are the same and composition ratios are different.

The fourth semiconductor layer 124 may be provided on an upper surface of the second active layer 123. The fourth semiconductor layer 124 may include, for example, an n-type semiconductor. As another example, the fourth semiconductor layer 124 may include a p-type semiconductor. The fourth semiconductor layer 124 may include a Group III-V based n-type semiconductor, for example, n-GaN, n-InGaN, n-AlInGaN, or n-AlGaInP. The fourth semiconductor layer 124 may have a single-layer structure or a multi-layer structure.

The light-emitting stack structure 10 may further include a third light-emitting element 130 disposed between the first light-emitting element 110 and the second light-emitting element 120. The third light-emitting element 130 may be disposed on an upper portion of the first light-emitting element 110 and a lower portion of the second light-emitting element 120. The third light-emitting element 130 may generate light of a third wavelength when voltage is applied thereto.

The third light-emitting element 130 may have a micro-sized width. For example, the width of the third light-emitting element 130 may be in the range from 0.1 μm to 100 μm. The width of the third light-emitting element 130 may be the same as the width of the first light-emitting element 110. However, the width of the third light-emitting element 130 is not limited thereto, and may be smaller than the width of the first light-emitting element 110.

The third light-emitting element 130 may include a fifth semiconductor layer 132, a third active layer 133 that emits light of the third wavelength and a sixth semiconductor layer 134.

The fifth semiconductor layer 132 may include a first type semiconductor. For example, the fifth semiconductor layer 132 may include a p-type semiconductor. As another example, the fifth semiconductor layer 132 may include an n-type semiconductor. The fifth semiconductor layer 132 may include a Group III-V based p-type semiconductor, for example, p-GaN, p-InGaN, p-AlInGaN, or p-AlGaInP. The fifth semiconductor layer 132 may have a single-layer structure or a multi-layer structure.

The third active layer 133 may be provided on an upper surface of the fifth semiconductor layer 132. The third active layer 133 may generate light of the third wavelength, and the third wavelength may be different from the first wavelength and the second wavelength. For example, the light of the third wavelength may have a green light wavelength, for example, light in the wavelength range of 530±20 nm. However, embodiments are not limited thereto.

The third active layer 133 may have an MQW structure or an SQW structure. The third active layer 133 may include a Group III-V semiconductor, for example, GaN, InGaN, AlInGaN, or AlGaInP. The third active layer 133 may include a material different from the material of the first active layer 113 and the material of the second active layer 123. Here, the different material may include not only cases in which constituent elements are different, but also cases in which constituent elements are the same and composition ratios are different.

The sixth semiconductor layer 134 may be provided on an upper surface of the third active layer 133. The sixth semiconductor layer 134 may include, for example, an n-type semiconductor. As another example, the sixth semiconductor layer 134 may include a p-type semiconductor. The sixth semiconductor layer 134 may include a Group III-V based n-type semiconductor, for example, n-GaN, n-InGaN, n-AlInGaN, or n-AlGaInP. The sixth semiconductor layer 134 may have a single-layer structure or a multi-layer structure.

When voltage is applied to the third light-emitting element 130, electrons and holes may be combined in the third active layer 133 to emit light of the third wavelength.

A current blocking layer may be disposed between the first light-emitting element 110 and the third light-emitting element 130 and between the third light-emitting element 130 and the second light-emitting element 120. The current blocking layer may prevent current from flowing between the first light-emitting element 110 and the third light-emitting element 130 and between the third light-emitting element 130 and the second light-emitting element 120.

However, the configuration of the third light-emitting element 130 is not limited thereto. For example, as shown in FIG. 3, the light-emitting stack structure 10 according to one or more embodiments may have a structure in which the first light-emitting element 110 and the second light-emitting element 120 are stacked without the third light-emitting element 130.

Referring back to FIGS. 1A and 1B, the micro light-emitting display apparatus according to one or more embodiments may include an electrode connection structure electrically connected to the first light-emitting element 110, the light-emitting element 120, and the third light-emitting element 130. In this regard, for example, the micro light-emitting display apparatus may include a plurality of via holes and a plurality of electrodes disposed in the plurality of via holes.

Referring to FIGS. 2 and 3, for example, the plurality of via holes may include a first upper via hole V11, a second upper via hole V12, and a third upper via hole V13. The first upper via hole V11 may extend downward from an upper surface of the light-emitting stack structure 10. The first upper via hole V11 may extend from the upper surface of the light-emitting stack structure 10 toward the second semiconductor layer 114 of the first light-emitting element 110. The second upper via hole V12 may extend downward from the upper surface of the light-emitting stack structure 10. The second upper via hole V12 may extend from the upper surface of the light-emitting stack structure 10 toward the fourth semiconductor layer 124 of the second light-emitting element 120. The third upper via hole V13 may extend downward from the upper surface of the light-emitting stack structure 10. The third upper via hole V13 may extend from the upper surface of the light-emitting stack structure 10 toward the sixth semiconductor layer 134 of the third light-emitting element 130. Here, the second upper via hole V12 may not be connected to the second light-emitting element 120 located on the top.

The plurality of via holes may further include a first lower via hole V21 and a second lower via hole V22. The first lower via hole V21 may extend upward from a lower surface of the light-emitting stack structure 10. The first lower via hole V21 may extend from the lower surface of the light-emitting stack structure 10 toward the third semiconductor layer 122 of the second light-emitting element 120. The second lower via hole V22 may extend upward from the lower surface of the light-emitting stack structure 10. The second lower via hole V22 may extend from the lower surface of the light-emitting stack structure 10 toward the fifth semiconductor layer 132 of the third light-emitting element 130.

The plurality of electrodes may be disposed in the first upper via hole V11, the second upper via hole V12, the third upper via hole V13, the first lower via hole V21, and the second lower via hole V22.

The first upper electrode 141 may be electrically and/or physically connected to the first light-emitting element 110. The first upper electrode 141 may penetrate the passivation layer 20, the second light-emitting element 120, and the third light-emitting element 130 to be in contact with the second semiconductor layer 114 of the first light-emitting element 110. The first upper electrode 141 may be disposed in the first upper via hole V11 and may be electrically and/or physically connected to the second semiconductor layer 114 of the first light-emitting element 110. The first upper electrode 141 may be a transparent electrode. For example, the first upper electrode 141 may be an indium tin oxide (ITO) electrode. However, the material of the first upper electrode 141 is not limited thereto, and may be various as necessary. For example, the first upper electrode 141 may not be a transparent electrode.

The second upper electrode 142 may be electrically and/or physically connected to the second light-emitting element 120. The second upper electrode 142 may be disposed to penetrate the passivation layer 20 to be in contact with the fourth semiconductor layer 124 of the second light-emitting element 120. The second upper electrode 142 may be disposed in the second upper via hole V12 and may be electrically and/or physically connected to the fourth semiconductor layer 124 of the second light-emitting element 120. The second upper electrode 142 may be a transparent electrode. For example, the second upper electrode 142 may be an ITO electrode. However, the material of the second upper electrode 142 is not limited thereto, and may be various as necessary. For example, the second upper electrode 142 may not be a transparent electrode.

The third upper electrode 143 may be electrically and/or physically connected to the third light-emitting element 130. The third upper electrode 143 may penetrate the passivation layer 20 and the second light-emitting element 120 to be in contact with the sixth semiconductor layer 134 of the third light-emitting element 130. The third upper electrode 143 may be disposed in the third upper via hole V13, and may be electrically and/or physically connected to the sixth semiconductor layer 134 of the third light-emitting element 130. The third upper electrode 143 may be a transparent electrode. For example, the third upper electrode 143 may be an ITO electrode. However, the material of the third upper electrode 143 is not limited thereto, and may be various as necessary. For example, the third upper electrode 143 may not be a transparent electrode.

The first upper electrode 141, the second upper electrode 142, and the third upper electrode 143 may be electrically and/or physically connected to each other. The first upper electrode 141, the second upper electrode 142, and the third upper electrode 143 may be connected to each other by a common electrode.

The first lower electrode 151 may be disposed in the first lower via hole V21 and may be electrically and/or physically connected to the third semiconductor layer 122 of the second light-emitting element 120. The second lower electrode 152 may be disposed in the second lower via hole V22 and may be electrically and/or physically connected to the fifth semiconductor layer 132 of the third light-emitting element 130. The third lower electrode 153 may be electrically and/or physically connected to the first semiconductor layer 112 of the first light-emitting element 110. The first lower electrode 151, the second lower electrode 152, and the third lower electrode 153 may each be a transparent electrode. For example, the first lower electrode 151, the second lower electrode 152, and the third lower electrode 153 may each be an ITO electrode. However, materials of the first lower electrode 151, the second lower electrode 152, and the third lower electrode 153 are not limited thereto, and may be various as necessary. For example, the first lower electrode 151, the second lower electrode 152, and the third lower electrode 153 may each not be a transparent electrode.

The first lower electrode 151, the second lower electrode 152, and the third lower electrode 153 may not be electrically and/or physically connected to each other.

The micro light-emitting display apparatus according to one or more embodiments may include the passivation layer 20 disposed on and to cover at least the upper surface of the light-emitting stack structure 10.

For example, the passivation layer 20 may be disposed on and to cover the upper surface of the light-emitting stack structure 10. The passivation layer 20 may be disposed on and to cover the upper surface of the second light-emitting element 120.

The passivation layer 20 may be disposed inside the first upper via hole V11, the second upper via hole V12, and the third upper via hole V13. The passivation layer 20 may be disposed on an inner surface of the first upper via hole V11. The passivation layer 20 may be disposed on an inner surface of the second upper via hole V12. The passivation layer 20 may be disposed on an inner surface of the third upper via hole V13. The passivation layer 20 may not be disposed on and spaced apart from the lower surface of the first upper via hole V11 for electrical connection of the first upper electrode 141. The passivation layer 20 may not be disposed on and spaced apart from the lower surface of the second upper via hole V12 for electrical connection of the second upper electrode 142. The passivation layer 20 may not be disposed on and spaced apart from the lower surface of the third upper via hole V13 for electrical connection of the third upper electrode 143.

For example, the passivation layer 20 may be disposed on and to cover the upper surface and a side surface of the light-emitting stack structure 10. For example, the passivation layer 20 may be disposed on and to cover the upper surface of the second light-emitting element 120, the side surface of the first light-emitting element 110, a side surface of the third light-emitting element 130, and a side surface of the second light-emitting element 120.

For example, the passivation layer 20 may be disposed on and to cover the upper surface, the side surface, and the lower surface of the light-emitting stack structure 10. For example, the passivation layer 20 may be disposed on and to cover the upper surface of the second light-emitting element 120, the side surface of the first light-emitting element 110, the side surface of the third light-emitting element 130, the side surface of the second light-emitting element 120, and the lower surface of the first light-emitting element 110. However, the passivation layer 20 may not be disposed on the lower surface of the first light-emitting element 110, and thus the passivation layer 20 may be omitted as necessary.

The passivation layer 20 may be disposed inside the first lower via hole V21 and the second lower via hole V22. The passivation layer 20 may be disposed on an inner surface of the first lower via hole V21. The passivation layer 20 may be disposed on an inner surface of the second lower via hole V22. The passivation layer 20 may not be disposed on the upper surface of the first lower via hole V21 for electrical connection with the first lower electrode 151. The passivation layer 20 may not be disposed on the upper surface of the second lower via hole V22 for electrical connection with the second lower electrode 152.

Referring to FIG. 4, the micro light-emitting display apparatus according to one or more embodiments may further include a backplane 30 disposed on the lower portion of the light-emitting stack structure 10. The backplane 30 may include a substrate 310 and a driving layer 320.

The substrate 310 may include an insulating material such as, for example, glass, an organic polymer, crystal, etc. In addition, the substrate 310 may include a flexible material to be bent or folded, and may have a single-layer structure or a multi-layer structure.

The driving layer 320 may be disposed on the substrate 310 and may include a plurality of transistors. The plurality of transistors may include a first transistor TR1 driving the first light-emitting element 110, a second transistor TR2 driving the second light-emitting element 120, and a third transistor TR3 driving the third light-emitting element 130. Each of the first transistor TR1, the second transistor TR2, and the third transistor TR3 may each include a semiconductor layer SC, a gate electrode G, a source electrode S, and a drain electrode D. The driving layer 320 may further include a driving voltage line, a scan driving unit, a data driving unit, and a processor.

Referring back to FIG. 2, light of different wavelengths may be respectively emitted simultaneously or at different times from the first light-emitting element 110, the second light-emitting element 120, and the third light-emitting element 130 of the light-emitting stack structure 10. Light of different colors emitted from the light-emitting stack structure 10 is emitted to the outside external to the micro light-emitting display apparatus through the passivation layer 20.

As described above, the micro light-emitting display apparatus according to one or more embodiments may have the passivation layer 20 including a plurality of passivation regions of different materials on the same plane in consideration of the fact that light of different wavelengths is emitted through the passivation layer 20. Accordingly, the light emission efficiency of the micro light-emitting display apparatus may be improved compared to the light emission efficiency of the passivation layer 20 of a single material.

The passivation layer 20 may include a first passivation region 210 including a first material to transmit the light of the first wavelength emitted from the first light-emitting element 110 to the outside and a second passivation region 220 including a second material to transmit the light of the second wavelength emitted from the second light-emitting element 120 to the outside.

The first material of the first passivation region 210 may include at least one of silicon oxide (SiO₂), aluminum nitride (AlN), aluminum oxynitride (AlON), tantalum pentaoxide (Ta₂O₅), silicon nitride (SiN), aluminum oxide (Al₂O₃), zirconium oxide (ZrO₂), or hafnium oxide (HfO₂). The first passivation region 210 may be a single layer, but is not necessarily limited thereto and may be a multilayer.

The second material of the second passivation region 220 may be a material different from the first material. The second material may include at least one of SiO₂, AlN, AlON, Ta₂O₅, SiN, Al₂O₃, ZrO₂, or HfO₂. The second passivation region 220 may be a single layer, but is not necessarily limited thereto and may be a multilayer.

When the first material of the first passivation region 210 includes any one of SiO₂, AlN, AlON, Ta₂O₅, SiN, Al₂O₃, ZrO₂, and HfO₂, the second material of the second passivation region 220 may include another one of SiO₂, AlN, AlON, Ta₂O₅, SiN, Al₂O₃, ZrO₂,and HfO₂ that is not included in the first passivation region 210. For example, when the first material includes AlON, the second material may include Ta₂O₅.

The first passivation region 210 and the second passivation region 220 may be disposed on the same plane. For example, the first passivation region 210 may be disposed on and to cover a partial region of the upper surface of the second light-emitting element 120. The first passivation region 210 may include a first upper passivation region 211 provided on and covering the partial region of the upper surface of the second light-emitting element 120. The second passivation region 220 may be provided on and cover another partial region of the upper surface of the second light-emitting element 120. The second passivation region 220 may include a second upper passivation region 221 covering the other partial region of the upper surface of the second light-emitting element 120.

The first passivation region 210 and the second passivation region 220 may have different materials and different thicknesses. For example, the first passivation region 210 and the second passivation region 220 are formed at different times in the manufacturing stage, and thus the thicknesses thereof may be different. For example, the thickness of the first passivation region 210 may be greater than the thickness of the second passivation region 220, or the thickness of the first passivation region 210 may be less than the thickness of the second passivation region 220. However, the thickness relationship between the first passivation region 210 and the second passivation region 220 is not necessarily limited thereto, and may be the same.

The first passivation region 210 may be disposed on and to cover a partial region of the side surface of the light-emitting stack structure 10. For example, the first passivation region 210 may include a first side passivation region 212 disposed on and to cover the partial region of the side surface of the light-emitting stack structure 10. For example, the first side passivation region 212 may be disposed on the left side with respect to FIG. 2.

The second passivation region 220 may be disposed on and to cover another partial region of the side surface of the light-emitting stack structure 10. For example, the second passivation region 220 may include a second side passivation region 222 disposed on and to cover the other partial region of the side surface of the light-emitting stack structure 10. For example, the second side passivation region 222 may be disposed on the right side with respect to FIG. 2.

In FIG. 2, an example in which the materials of the first side passivation region 212 and the second side passivation region 222 of the passivation layer 20 are different is described, but the passivation layer 20 according to embodiments are not limited thereto. For example, the material of the first side passivation region 212 and the second side passivation region 222 of the passivation layer 20 disposed on the side surface of the light-emitting stack structure 10 may be the same.

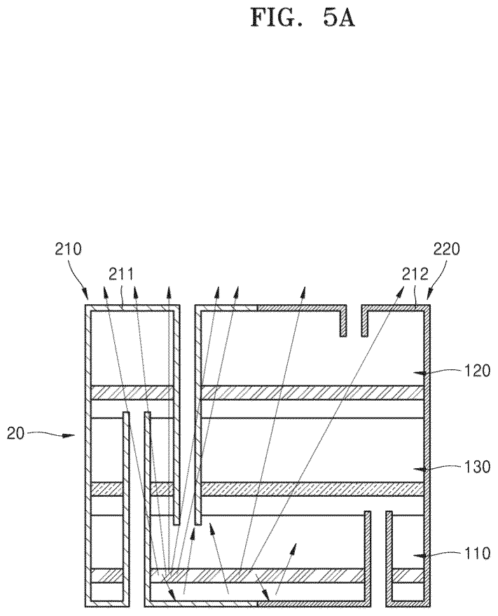

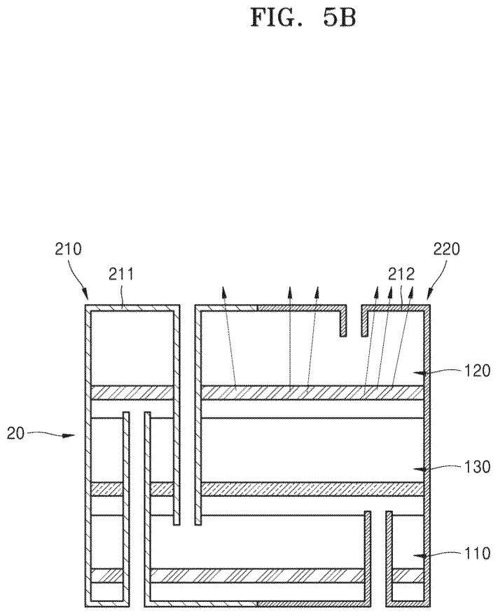

FIG. 5A is a diagram for explaining light of a first wavelength being emitted from a micro light-emitting display apparatus according to one or more embodiments, and FIG. 5B is a diagram for explaining light of a second wavelength being emitted from the micro light-emitting display apparatus according to one or more embodiments. For convenience of description, an upper electrode and a lower electrode disposed in an upper via hole and a lower via hole are not shown in FIGS. 5A and 5B.

Referring to FIG. 5A, when a voltage is applied to the first light-emitting element 110 of the micro light-emitting display apparatus according to one or more embodiments, light of the first wavelength may be generated in the first light-emitting element 110. The generated light of the first wavelength is emitted to the outside after passing through the second light-emitting element 120, the third light-emitting element 130, and the passivation layer 20. Because the first passivation region 210 of the passivation layer 20 includes a material having significantly high light emission efficiency with respect to the light of the first wavelength, the light of the first wavelength may be mainly emitted through the first passivation region 210 of the passivation layer 20. The light of the first wavelength may be mainly emitted through the first upper passivation region 211 of the first passivation region 210.

Referring to FIG. 5B, when a voltage is applied to the second light-emitting element 120 of the micro light-emitting display apparatus according to one or more embodiments, the light of the second wavelength may be generated by the second light-emitting element 120. The generated light of the second wavelength is emitted to the outside after passing through the passivation layer 20. Because the second passivation region 220 of the passivation layer 20 includes a material having significantly high light emission efficiency with respect to the light of the second wavelength, the light of the second wavelength may be mainly emitted through the second passivation region 220 of the passivation layer 20. The light of the second wavelength may be mainly emitted through the second upper passivation region 221 of the second passivation region 220.

As described above, the passivation layer 20 includes a plurality of passivation regions including materials corresponding to light of wavelengths, and thus the overall light emission efficiency may be improved.

When the passivation layer 20 includes one material corresponding to the light of the first wavelength, the light emission efficiency with respect to the light of the first wavelength may be relatively high, but the light emission efficiency with respect to the light of the second wavelength may be rapidly reduced. When the passivation layer 20 includes one material corresponding to the light of the second wavelength, the light emission efficiency with respect to the light of the second wavelength may be relatively high, but the light emission efficiency with respect to the light of the first wavelength may be rapidly reduced.

On the other hand, the passivation layer 20 according to one or more embodiments includes a plurality of passivation regions including different materials, thereby obtaining overall satisfactory light emission efficiency with respect to a plurality of lights emitted from the micro light-emitting display apparatus.

Referring back to FIGS. 1A and 1B, the first passivation region 210 and the second passivation region 220 may be disposed so as not to overlap each other in a horizontal direction perpendicular to a stacking direction (vertical direction). For example, the first upper passivation region 211 and the second upper passivation region 221 may be disposed so as not to overlap each other in the horizontal direction. For example, the sum of the area occupied by the first upper passivation region 211 and the area occupied by the second upper passivation region 221 may be less than or equal to the area of the upper surface of the light-emitting stack structure 10. For example, the area occupied by the first upper passivation region 211 may be 50% or less of the area of the upper surface of the light-emitting stack structure 10, and the area occupied by the second upper passivation region 221 may be 50% or less of the area of the upper surface of the light-emitting stack structure 10.

The first passivation region 210 may be disposed adjacent to the first upper electrode 141, and the second passivation region 220 may be disposed adjacent to the second upper electrode 142 and the third upper electrode 143. For example, the first passivation region 210 may be disposed to surround the first upper electrode 141 on the upper surface of the light-emitting stack structure 10, and the second passivation region 220 may be disposed adjacent to and to surround the second upper electrode 142 and the third upper electrode 143 on the upper surface of the light-emitting stack structure 10. However, the division and boundary of the passivation layer 20 are not necessarily limited thereto, and may be modified in various ways.

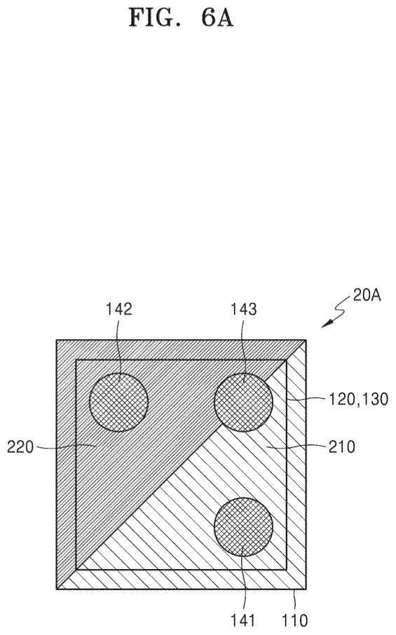

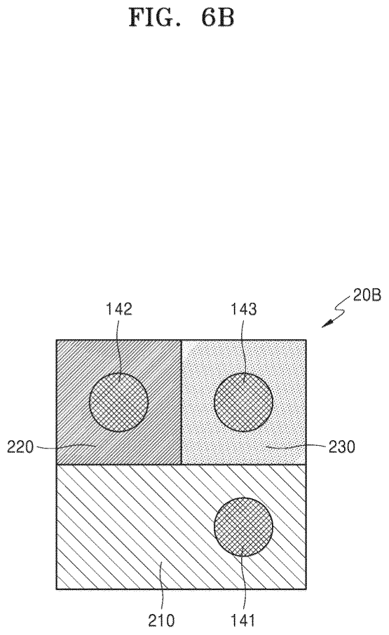

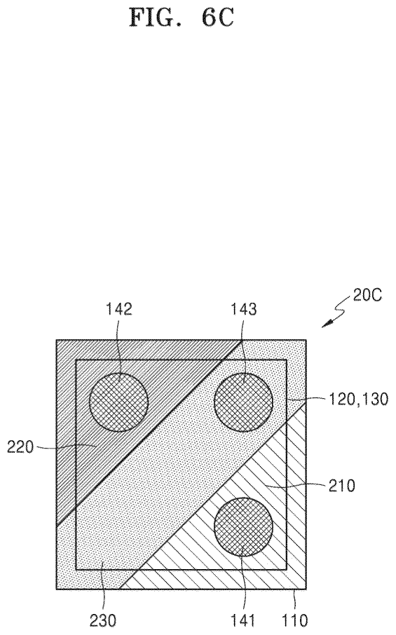

FIGS. 6A to 6C are plan views illustrating various examples of a micro light-emitting display apparatus according to one or more embodiments.

Referring to FIG. 6A, in a passivation layer 20A of the micro light-emitting display apparatus according to one or more embodiments, the first passivation region 210 may be adjacent to and surround a part of each of the first upper electrode 141 and the second upper electrode 142 on the upper surface of the light-emitting stack structure 10, and the second passivation region 220 may surround a part of each of the second upper electrode 142 and the third upper electrode 143 on the upper surface of the light-emitting stack structure 10. A width of the first light-emitting element 110 disposed below the second light-emitting element 120 may be greater than a width of the second light-emitting element 120 disposed above the first light-emitting element 110. However, the width of the first light-emitting element 110 and the width of the second light-emitting element 120 are not limited thereto, and may be the same.

Referring to FIGS. 6B and 6C, passivation layers 20B and 20C may further include a third passivation region 230. The third passivation region 230 may have a third material to transmit light of a third wavelength of the third light-emitting element 130 to the outside. The third material may include at least one of SiO₂, AlN, AlON, Ta₂O₅, SiN, Al₂O₃, ZrO₂, or HfO₂. The third material may be different from a first material and a second material. For example, when the first material includes any one of SiO₂, AlN, AlON, Ta₂O₅, SiN, Al₂O₃, ZrO₂, and HfO₂, and the second material includes any one of SiO₂, AlN, AlON, Ta₂O₅, SiN, Al₂O₃, ZrO₂, and HfO₂, the third material may include another one of SiO₂, AlN, AlON, Ta₂O₅, SiN, Al₂O₃, ZrO₂, and HfO₂.

The third passivation region 230 may be disposed on the same plane as the first passivation region 210 and the second passivation region 220. The first passivation region 210 may be disposed on a first part of the passivation layer 20, the second passivation region 220 may be disposed on a second part of the passivation layer 20 different from the first part of the passivation layer 20, and the third passivation region 230 may be disposed on a third part of the passivation layer 20 different from the first part and second part of the passivation layer 20. A first partial region of an upper surface of the second light-emitting element 120 may be covered by the first passivation region 210, a second partial region of the upper surface of the second light-emitting element 120 may be covered by the second passivation region 220, and a third partial region of the upper surface of the second light-emitting element 120 other than the first and second partial regions of the upper surface of the second light-emitting element 120 may be covered by the third passivation region 230. For example, the first passivation region 210 may be disposed adjacent to the first upper electrode 141, the second passivation region 220 may be disposed adjacent to the second upper electrode 142, and the third passivation region 230 may be disposed adjacent to the third upper electrode 143. For example, the first passivation region 210 may be disposed adjacent to and to surround the first upper electrode 141 on the upper surface of the second light-emitting element 120, the second passivation region 220 may be disposed adjacent to and to surround the second upper electrode 142 on the upper surface of the second light-emitting element 120, and the third passivation region 230 may be disposed adjacent to and to surround the third upper electrode 143 on the upper surface of the second light-emitting element 120. The shapes of the first passivation region 210, the second passivation region 220, and the third passivation regions 230 disposed on the upper surface of the second light-emitting element 120 may vary, as shown in FIGS. 6B and 6C.

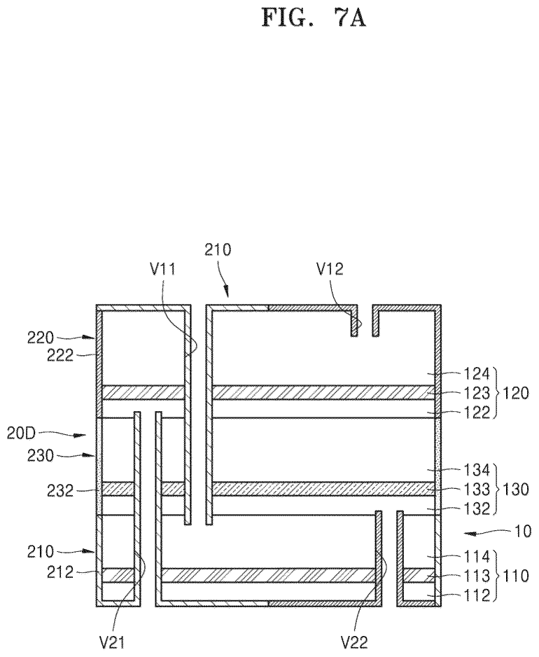

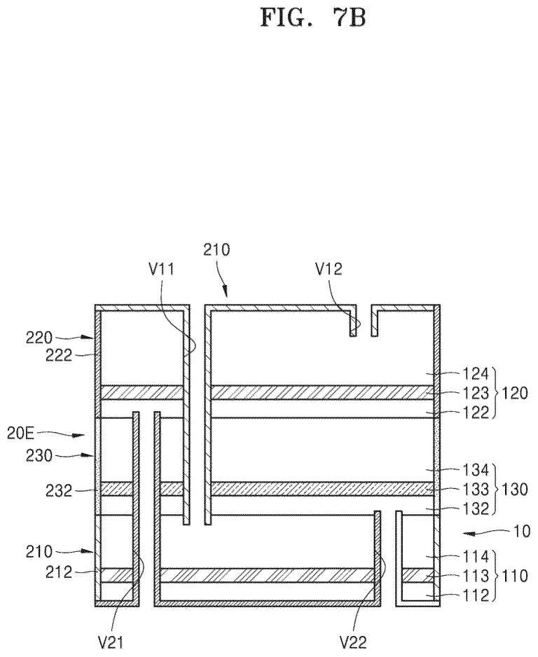

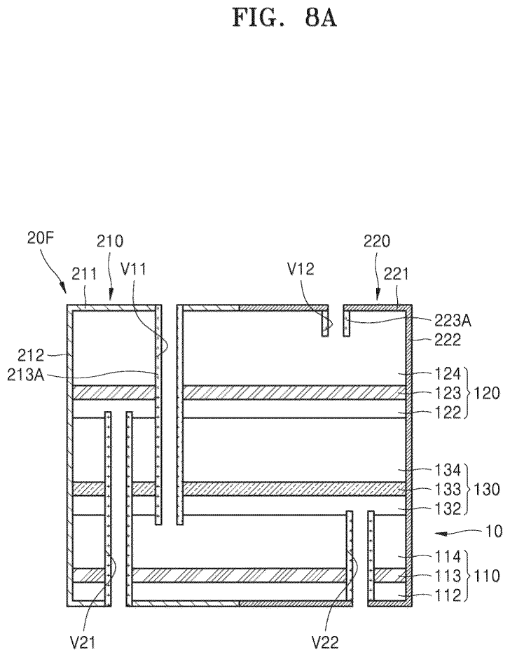

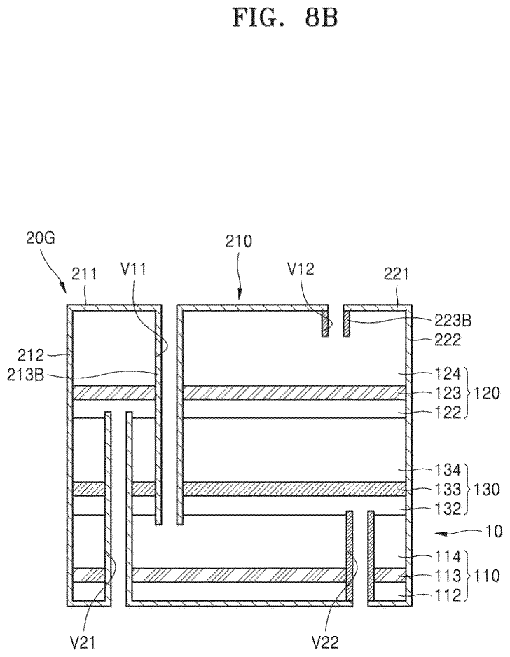

FIGS. 7A and 7B are diagrams illustrating another example of a micro light-emitting display apparatus according to one or more embodiments. FIGS. 8A and 8B are diagrams illustrating another example of a micro light-emitting display apparatus according to one or more embodiments.

In the above-described embodiments, as an example in which a plurality of passivation regions including different materials of the passivation layer 20 are disposed on the same plane, a structure in which the plurality of passivation regions are differently disposed in the upper surface and the lower surface of the light-emitting stack structure 10 has been described. However, the structure in which the plurality of passivation regions are disposed on the same plane is not limited thereto.

For example, as shown in FIG. 7A and FIG. 7B, the passivation layer 20 may include the plurality of passivation regions including different materials on the side surface of the light-emitting stack structure 10. For example, the plurality of passivation regions may be disposed on side surfaces of a plurality of light-emitting elements, respectively. For example, the first passivation region 210 may include the first side passivation region 212 provided on and covering a side surface of the first light-emitting element 110, the second passivation region 220 may include the second side passivation region 222 provided on and covering a side surface of the second light-emitting element 120, and the third passivation region 230 may include the third side passivation region 232 provided on and covering a side surface of the third light-emitting element 130. The first side passivation region 212, the second side passivation region 222, and the third side passivation region 232 may be disposed on the same plane in the side surface of the light-emitting stack structure 10. At this time, the first passivation region 210 may cover a partial region of the upper surface of the second light-emitting element 120 as shown in FIG. 7A or the entire area of the upper surface of the second light-emitting element 120 as shown in FIG. 7B.

Here, being disposed on the same plane may indicate being disposed on the same surface of the light-emitting stack structure 10. For example, being disposed on the same plane may indicate being disposed on the same layer.

Referring back to FIG. 2, the passivation layer 20 may include a plurality of hole passivation regions disposed in a plurality of via holes, respectively. For example, the first passivation region 210 may include the first hole passivation region 213 disposed in the first upper via hole V11. The second passivation region 220 may include the second hole passivation region 223 disposed in the second upper via hole V12.

The first hole passivation region 213 may be disposed between the inner surface of the first upper via hole V11 and the first upper electrode 141. The first hole passivation region 213 may include a first material. The first material may include at least one of SiO₂, AlN, AlON, Ta₂O₅, SiN, Al₂O₃, ZrO₂, or HfO₂. The first hole passivation region 213 may be a single layer, but is not necessarily limited thereto and may be a multilayer.

As the first hole passivation region 213 includes the first material, light emission efficiency may be improved when part of the light of the first wavelength generated by the first light-emitting element 110 is emitted to the outside through the first hole passivation region 213 and the first upper electrode 141. The first hole passivation region 213 may extend from the first upper passivation region 211.

The second hole passivation region 223 may be disposed between the inner surface of the second upper via hole V12 and the second upper electrode 142. The second hole passivation region 223 may include a second material. The second material may include at least one of SiO₂, AlN, AlON, Ta₂O₅, SiN, Al₂O₃, ZrO₂, or HfO₂. The second hole passivation region 223 may be a single layer, but is not limited thereto and may be a multi-layer. As the second hole passivation region 223 includes the second material, light emission efficiency may be improved when part of the light of the second wavelength generated by the second light-emitting element 120 is emitted to the outside through the second hole passivation region 223 and the second upper electrode 142. The second hole passivation region 223 may extend from the second upper passivation region 221.

In the above-described example, a hole passivation region extends from an adjacent upper passivation region, but the disclosure is not necessarily limited thereto. For example, as shown in FIGS. 8A and 8B, a plurality of hole passivation regions 213A, 223A, 213B, and 223B of passivation layers 20F and 20G according to one or more embodiments may each have a material different from a material of the adjacent upper passivation region. For example, as shown in FIG. 8A, the plurality of hole passivation regions 213A and 223A of the passivation layer 20F according to one or more embodiments may have the same material. For example, as shown in FIG. 8B, at least one of the plurality of hole passivation regions 213B and 223B of the passivation layer 20G according to one or more embodiments may have a material different from a material of the other hole passivation region.

Referring back to FIG. 2, the passivation layer 20 of the micro light-emitting display apparatus includes the first passivation region 210 and the second passivation region 220 disposed on the same plane. As the first passivation region 210 and the second passivation region 220 are disposed on the same plane, one end portion of the first passivation region 210 and one end portion of the second passivation region 220 may be disposed to face each other on the same plane.

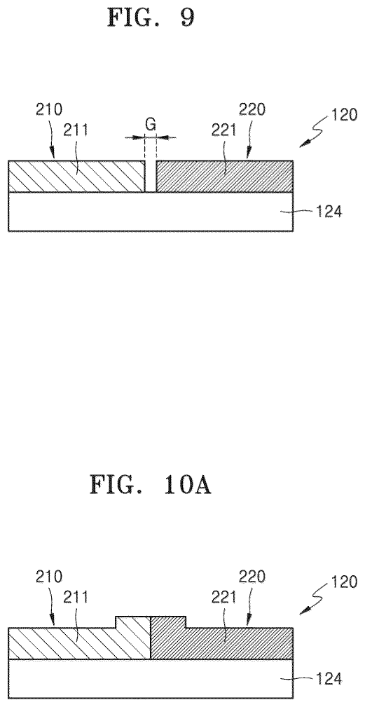

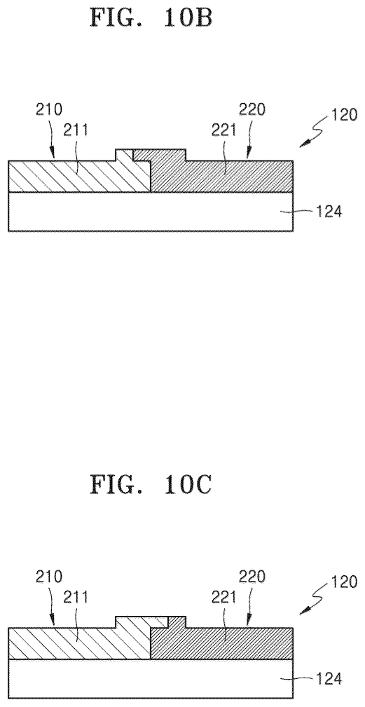

FIG. 9 is a diagram illustrating an example of part A that is a boundary between a plurality of passivation regions in the micro light-emitting display apparatus of FIG. 2. FIGS. 10A to 10C are diagrams illustrating other examples of the part A that is the boundary between the plurality of passivation regions in the micro light-emitting display apparatus of FIG. 2.

For example, referring to FIG. 9, the first passivation region 210 and the second passivation region 220 of the passivation layer 20 according to one or more embodiments may not be in contact with and spaced apart from each other. The first upper passivation region 211 and the second upper passivation region 221 may not be in contact with and spaced apart from each other. An end portion of the first upper passivation region 211 and an end portion of the second upper passivation region 221 may be spaced apart from each other. A gap G may exist between the first upper passivation region 211 and the second upper passivation region 221. The gap G between the first upper passivation region 211 and the second upper passivation region 221 may correspond to a thickness of the first upper passivation region 211 or a thickness of the second upper passivation region 221. For example, the gap G between the first upper passivation region 211 and the second upper passivation region 221 may be 80% to 120% of the thickness of the first upper passivation region 211 or the thickness of the second upper passivation region.

As another example, referring to FIGS. 10A to 10C, the first passivation region 210 and the second passivation region 220 may be in contact with each other. For example, an end portion of a boundary part of the first upper passivation region 211 and an end portion of a boundary part of the second upper passivation region 221 may contact each other. For example, a thickness of a boundary part where the first passivation region 210 and the second passivation region 220 are in contact with each other may be greater than thicknesses of other parts of the first passivation region 210 and the second passivation region 220. In a part of the boundary part between the first passivation region 210 and the second passivation region 220, the second passivation region 220 may be located in an upper portion of the first passivation region 210 as shown in FIG. 10B or the first passivation region 210 may be located in an upper portion of the second passivation region 220 as shown in FIG. 10C.

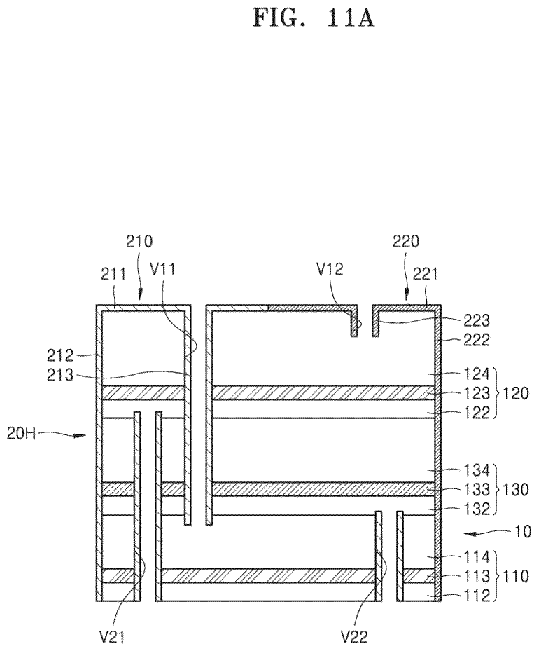

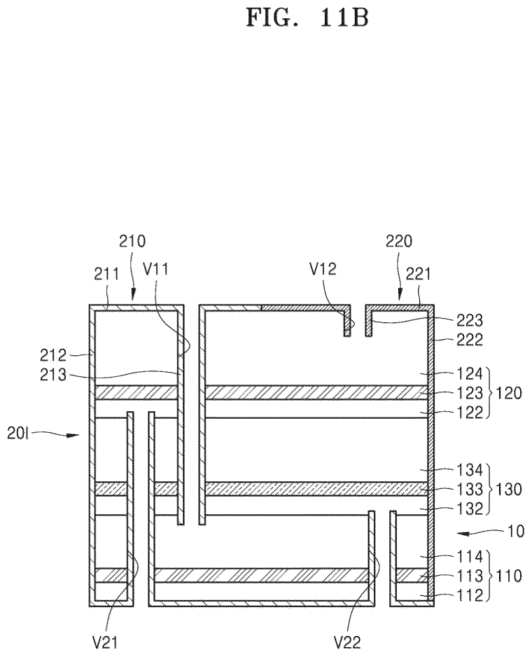

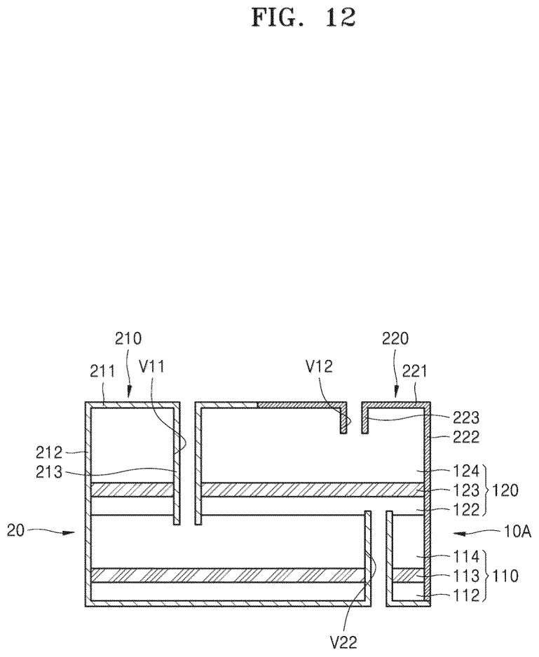

In the above-described embodiments, the examples in which the light-emitting stack structure 10 of the micro light-emitting display apparatus emits three colors of light, and the passivation layer 20 is disposed on and to cover the upper surface, the side surface, and the lower surface of the light-emitting stack structure 10 have been described. However, the micro light-emitting display apparatus is not necessarily limited thereto, and may be modified in various ways. For example, in the micro light-emitting display apparatus according to one or more embodiments as shown in FIG. 11A, a passivation layer 20H may not be disposed on the lower surface of the light-emitting stack structure 10. For example, in the micro light-emitting display apparatus according to one or more embodiments, as shown in FIG. 11B, a material of a passivation layer 20I disposed on the lower surface of the light-emitting stack structure 10 may be the same. For example, as shown in FIG. 12, a light-emitting stack structure 10A of the micro light-emitting display apparatus according to one or more embodiments may include the first light-emitting element 110 and the second light-emitting element 120 without the third light-emitting element 130. Such a micro light-emitting display apparatus may be applied to, for example, a pentile pixel structure. The pentile pixel structure may share subpixels with other neighboring pixels. In the pentile pixel structure, one pixel may include, for example, a red sub-pixel and a green sub-pixel, or a blue sub-pixel and a green sub-pixel. However, this is only an example, and various pixel structures are possible.

Hereinafter, a method of manufacturing the above-described micro light-emitting display apparatus will be described.

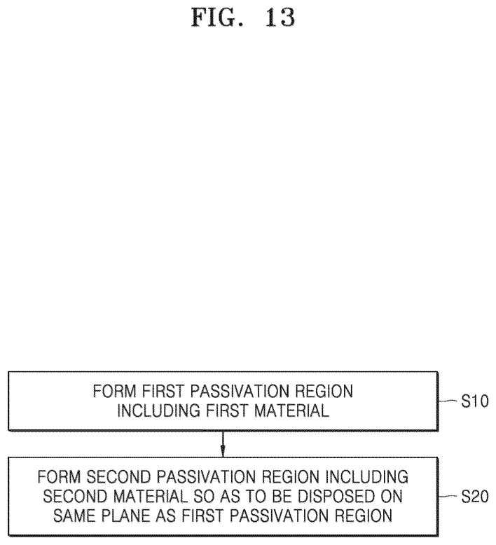

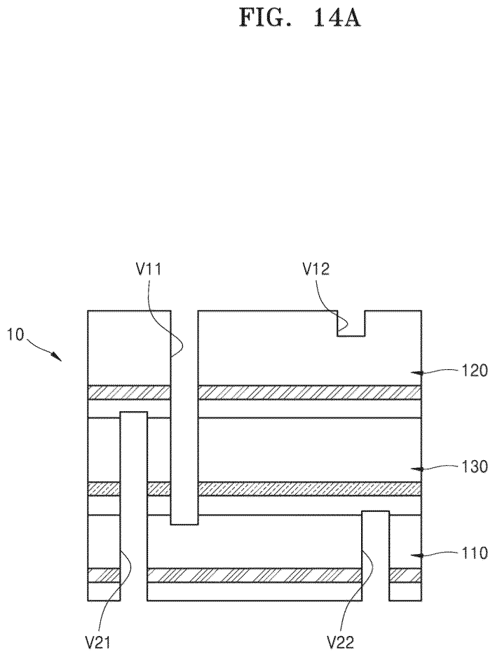

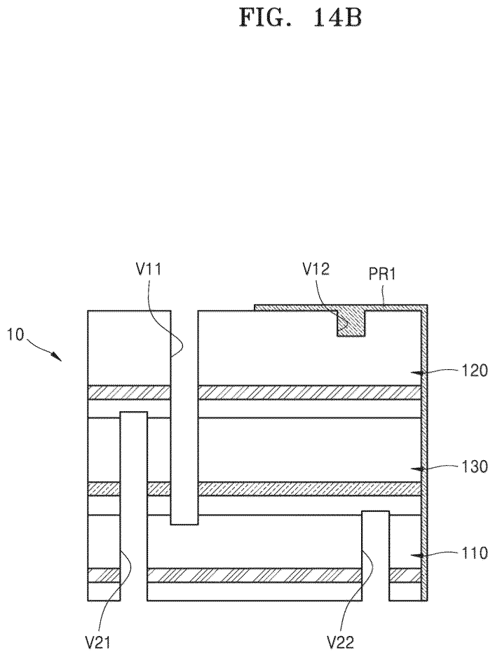

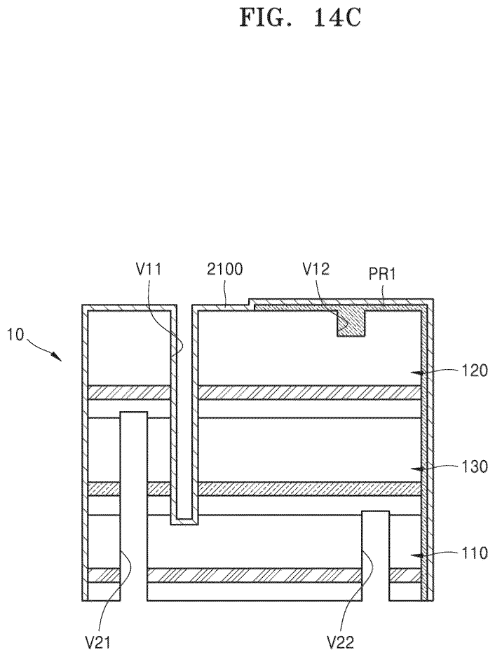

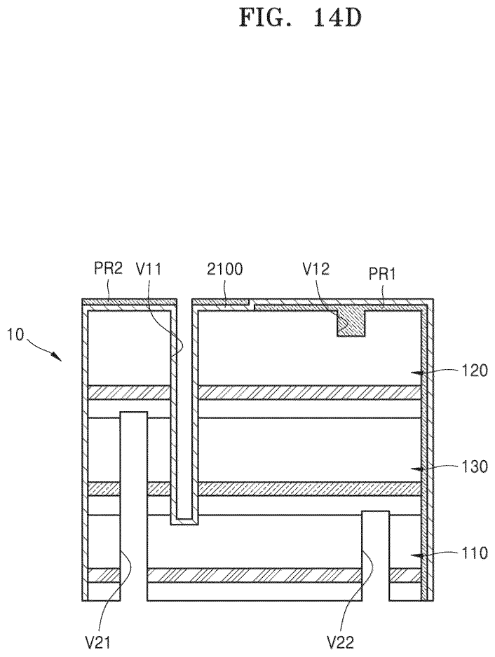

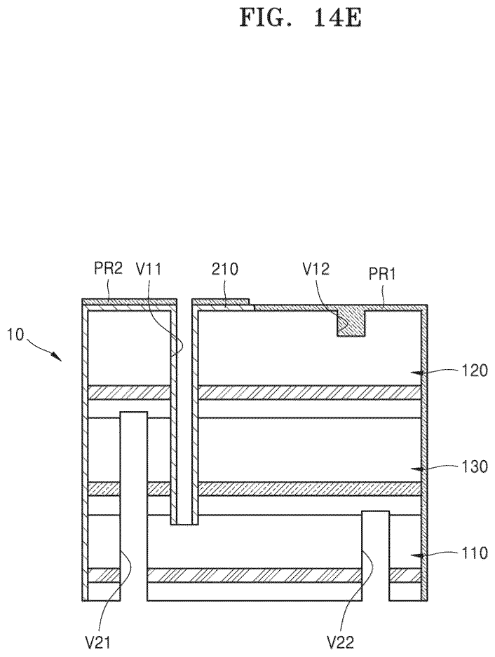

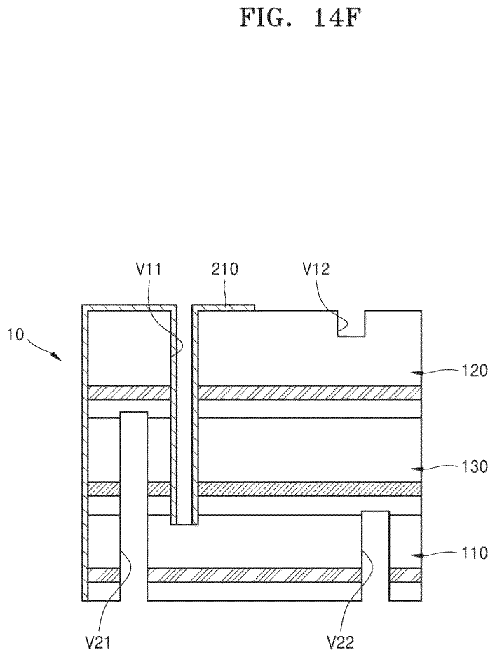

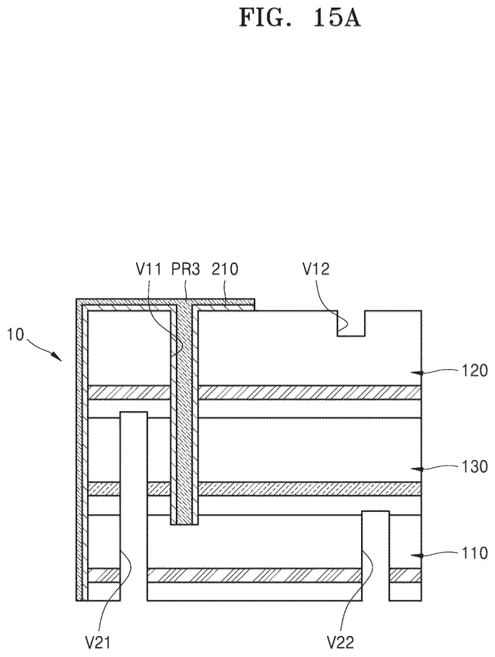

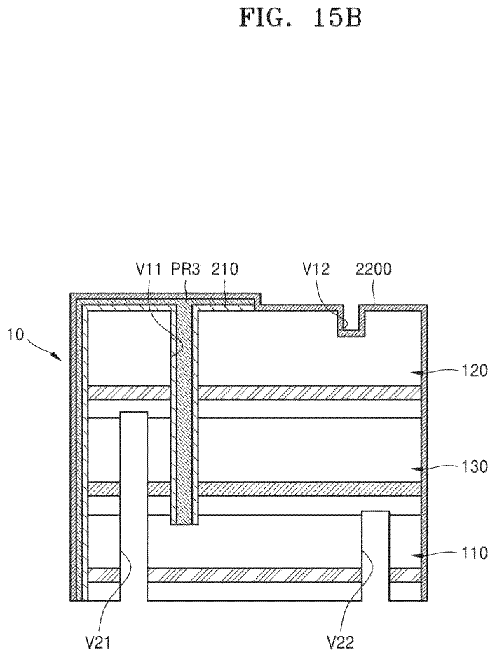

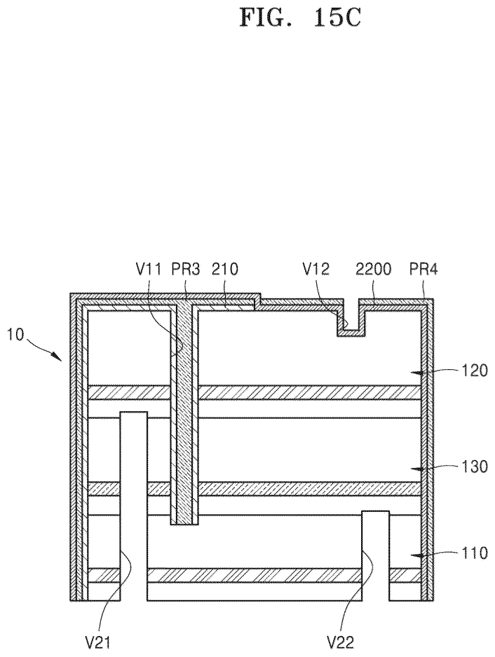

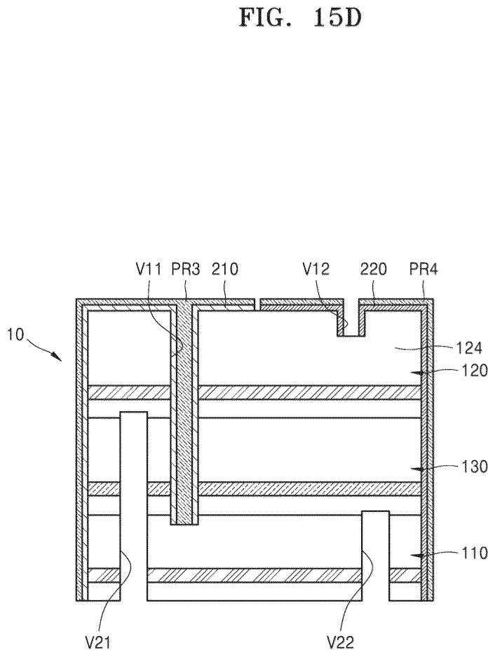

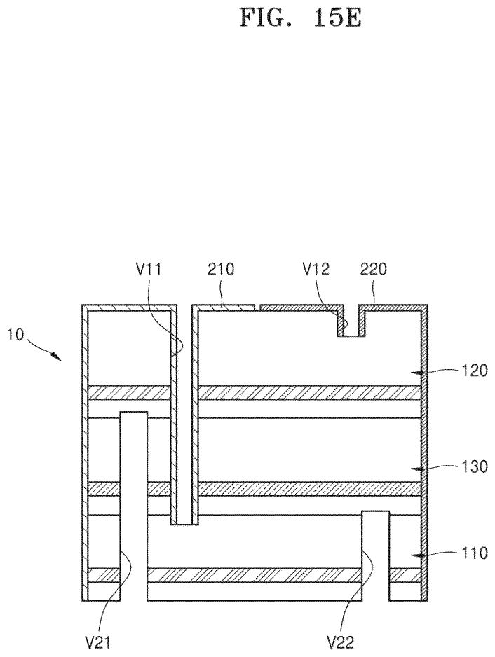

FIG. 13 is a flowchart illustrating a method of manufacturing a micro light-emitting display apparatus according to one or more embodiments. FIGS. 14A to 14F are diagrams illustrating an example of an operation of forming the first passivation region 210 in the method of manufacturing the micro light-emitting display apparatus according to one or more embodiments. FIGS. 15A to 15E are diagrams illustrating an example of an operation of forming the second passivation region 220 in the method of manufacturing the micro light-emitting display apparatus according to one or more embodiments.

Referring to FIG. 13, according to one or more embodiments a first passivation region 210 including a first material may be formed (S10).

The first passivation region 210 may partially form the first passivation region 210 on the light-emitting stack structure 10 in which a plurality of light-emitting elements are stacked. For example, the first passivation region 210 may be formed on a part of an upper surface of the light-emitting stack structure 10. For example, the first passivation region 210 may be formed on the part of the upper surface and a part of a side surface of the light-emitting stack structure 10.

Referring to FIG. 14A, the light-emitting stack structure 10 may have a structure in which the first light-emitting element 110, the third light-emitting element 130, and the second light-emitting element 120 are sequentially stacked. The light-emitting stack structure 10 may include a plurality of upper via holes and a plurality of lower via holes. The plurality of upper via holes may include the first upper via hole V11 and the second upper via hole V12 which extend downward from the upper surface of the light-emitting stack structure 10, and have different depths. The plurality of lower via holes may include the first lower via hole V21 and the second lower via hole V22 which extend upward from the lower surface of the light-emitting stack structure 10, and have different depths.

The light-emitting stack structure 10 may be disposed such that the first upper via hole V11 and the second upper via hole V12 face upward.

Referring to FIG. 14B, a first photoresist PR1 may be formed on the light-emitting stack structure 10 to expose a position where the first passivation region 210 is to be formed. The first photoresist PR1 may include a photosensitive material. The first photoresist PR1 may be a positive photosensitive material or a negative photosensitive material. The first photoresist PR1 may be formed to have a certain shape by a photolithography process.

The first photoresist PR1 may be formed to expose the first upper via hole V11 and fill the second upper via hole V12. The first photoresist PR1 may fill the second upper via hole V12, and may be disposed on a peripheral part of the second upper via hole V12 and one side surface of the light-emitting stack structure 10 on the upper surface of the second light-emitting element 120. The first photoresist PR1 may be formed not to be filled in the first upper via hole V11.

Referring to FIG. 14C, a first passivation preparation layer 2100 may be formed on the light-emitting stack structure 10 in which the first photoresist PR1 is formed. The first passivation preparation layer 2100 may include a first material. The first material may include at least one of SiO₂, AlN, AlON, Ta₂O₅, SiN, Al₂O₃, ZrO₂, or HfO₂.

The first passivation preparation layer 2100 may be disposed on the light-emitting stack structure 10 by a deposition process. The first passivation preparation layer 2100 may be formed using a chemical vapor deposition (CVD) process, a physical vapor deposition (PVD) process, or an atomic layer deposition (ALD) process.

The first passivation preparation layer 2100 may be disposed on an upper surface of the first photoresist PR1, the upper surface of the second light-emitting element 120 and the other side surface of the light-emitting stack structure 10 on which the first photoresist PR1 is not disposed. The first passivation preparation layer 2100 may be disposed along an inner surface of the first upper via hole V11.

Referring to FIG. 14D, a second photoresist PR2 may be formed so as not to overlap the first photoresist PR1 in the light-emitting stack structure 10 in which the first passivation preparation layer 2100 is formed. The second photoresist PR2 may include a photosensitive material. The second photoresist PR2 may be a positive photosensitive material or a negative photosensitive material. The second photoresist PR2 may be formed to have a certain shape by a photolithography process.

The second photoresist PR2 may be formed to expose a lower surface of the first upper via hole V11. The second photoresist PR2 is disposed on a peripheral part of the first upper via hole V11 and one side surface of the light-emitting stack structure 10 on the upper surface of the second light-emitting element 120.

Referring to FIG. 14E, the first passivation preparation layer 2100 may be patterned to have a certain shape by an etching process. In the etching process, the second photoresist PR2 may function as an etching mask.

A part of the first passivation preparation layer 2100 that is not covered and exposed by the second photoresist PR2 may be removed. A part of the first passivation preparation layer 2100 disposed on the first photoresist PR1 and a part thereof disposed on the lower surface of the first upper via hole V11 may be removed. Accordingly, only a region of the first passivation preparation layer 2100 disposed in a lower portion of the second photoresist PR2 remains. The first passivation preparation layer 2100 patterned by the etching process may be defined as the first passivation region 210.

Referring to FIG. 14F, a photoresist may be removed from the light-emitting stack structure 10 in which the first passivation region 210 is formed. The first photoresist PR1 and the second photoresist PR2 may be removed from the light-emitting stack structure 10. Accordingly, the first passivation region 210 partially disposed on the light-emitting stack structure 10 may be formed. The first passivation region 210 may be formed on and to cover a partial region of the upper surface of the light-emitting stack structure 10. The first passivation region 210 may be formed on and to cover a partial region of the side surface of the light-emitting stack structure 10.

Referring back to FIG. 13, according to one or more embodiments a second passivation region 220 including a second material may be formed (S20). The second passivation region 220 may be formed on the light-emitting stack structure 10 to be provided on and cover another partial region on the same plane as the first passivation region 210.

Referring to FIG. 15A, a third photoresist PR3 may be formed on the light-emitting stack structure 10 in which the first passivation region 210 is formed. For example, the third photoresist PR3 may be disposed on the upper surface of the first passivation region 210 and may be filled in the first upper via hole V11.

The third photoresist PR3 may include a photosensitive material. The third photoresist PR3 may be a positive photosensitive material or a negative photosensitive material. The third photoresist PR3 may be formed to have a certain shape by a photolithography process.

Referring to FIG. 15B, a second passivation preparation layer 2200 may be formed on the light-emitting stack structure 10 in which the third photoresist PR3 is formed. The second passivation preparation layer 2200 may include a second material. The second material may include at least one of SiO₂, AlN, AlON, Ta₂O₅, SiN, Al₂O₃, ZrO₂, or HfO₂. The second material may be a material different from the first material.

The second passivation preparation layer 2200 may be disposed on the light-emitting stack structure 10 by a deposition process. The second passivation preparation layer 2200 may be formed using a chemical vapor deposition (CVD) process, a physical vapor deposition (PVD) process, or an atomic layer deposition (ALD) process.

The second passivation preparation layer 2200 may be deposited on exposed upper surface and side surface of the light-emitting stack structure 10. For example, the second passivation preparation layer 2200 may be formed to be disposed on an upper portion of the third photoresist PR3, the upper portion of the second light-emitting element 120, the side portion of the second light-emitting element 120, the side portion of the third light-emitting element 130, the side portion of the first light-emitting element 110, and the inner surface of the second upper via hole V12.

Referring to FIG. 15C, a fourth photoresist PR4 may be formed on a region where the second passivation region 220 may be formed. The fourth photoresist PR4 may include a photosensitive material. The fourth photoresist PR4 may be a positive photosensitive material or a negative photosensitive material. The fourth photoresist PR4 may be formed to have a certain shape by a photolithography process.

The fourth photoresist PR4 may be disposed not to overlap the first passivation region 210. The fourth photoresist PR4 may not overlap the third photoresist PR3. The fourth photoresist PR4 may expose the lower surface of first upper via hole V11. The third photoresist PR3 disposed on the first passivation region 210 and the fourth photoresist PR4 disposed on the second passivation preparation layer 2200 may be spaced apart from each other.

Referring to FIG. 15D, the second passivation preparation layer 2200 may be patterned to have a certain shape by an etching process. In the etching process, the fourth photoresist PR4 may function as an etching mask.

A region of the second passivation preparation layer 2200 that is not covered and exposed by the fourth photoresist PR4 may be removed. A region of the second passivation preparation layer 2200 covered by the fourth photoresist PR4 remains, and a region of the second passivation preparation layer 2200 that is not covered and exposed by the fourth photoresist PR4 may be removed. The second passivation preparation layer 2200 patterned by the etching process may be defined as the second passivation region 220.

In the etching process, a part of the second passivation preparation layer 2200 between the third photoresist PR3 and the fourth photoresist PR4 may be removed. Accordingly, the first passivation region 210 and the second passivation region 220 may be spaced apart from each other.

However, the first passivation region 210 and the second passivation region 220 are not necessarily spaced apart from each other, and according to an etching rate or the shape of the mask, the first passivation region 210 and the second passivation region 220 may be formed to contact each other.

Referring to FIG. 15E, a photoresist may be removed from the light-emitting stack structure 10 in which the first passivation region 210 and the second passivation region 220 are formed. The third photoresist PR3 and the fourth photoresist PR4 may be removed from the light-emitting stack structure 10. Accordingly, the micro light-emitting display apparatus including the passivation layer 20 including the first passivation region 210 and the second passivation region 220 disposed on the same plane may be manufactured.

The second passivation region 220 may be formed not to overlap the first passivation region 210. The second passivation region 220 may be formed to be provided on and cover another partial region in which the first passivation region 210 is not formed on the upper surface of the light-emitting stack structure 10. The second passivation region 220 may be formed to cover another partial region in which the first passivation region 210 is not formed on the side surface of the light-emitting stack structure 10.

In an operation before or after forming the first passivation region 210 and the second passivation region 220, a process of forming the passivation layer 20 on the lower surface of the light-emitting stack structure 10 and inner surfaces of the plurality of lower via holes may be performed. In this regard, an operation similar to the operation of forming the passivation layer 20 described above is performed, and thus a detailed description thereof is omitted.

In the above-described embodiment, an example in which the first passivation region 210 includes the first upper passivation region 211, the first side passivation region 212, and the first hole passivation region 213, and the second passivation region 220 includes the second upper passivation region 221, the second side passivation region 222, and the second hole passivation region 223 has been mainly described. However, the shapes and methods of the first passivation region 210 and the second passivation region 220 are not necessarily limited thereto.

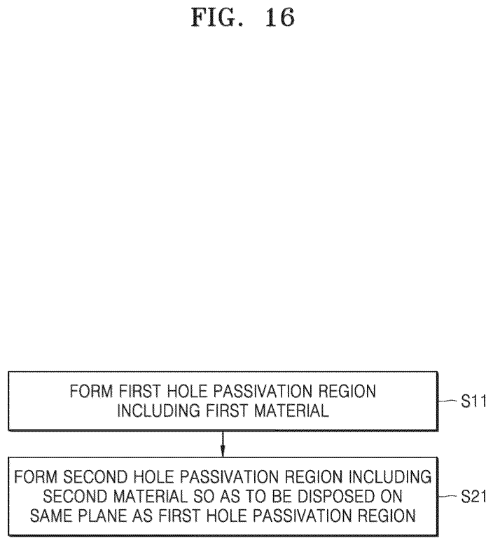

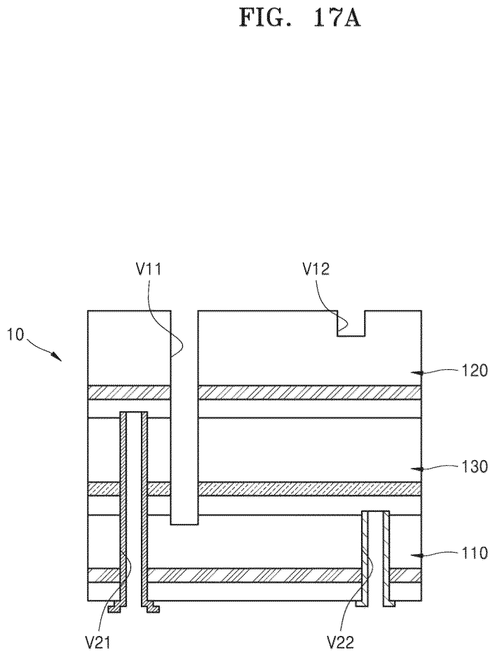

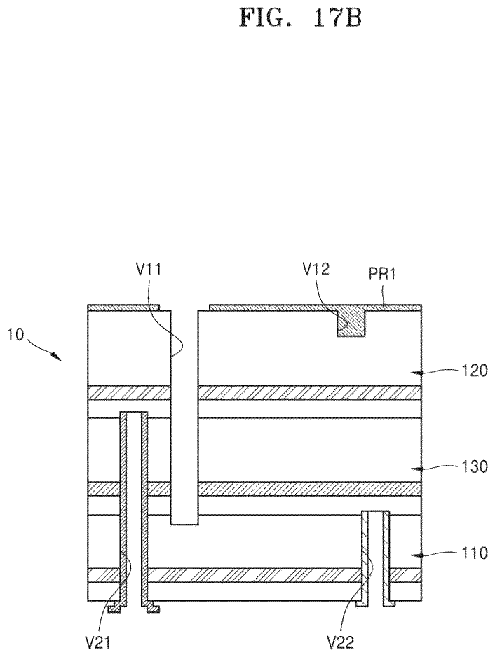

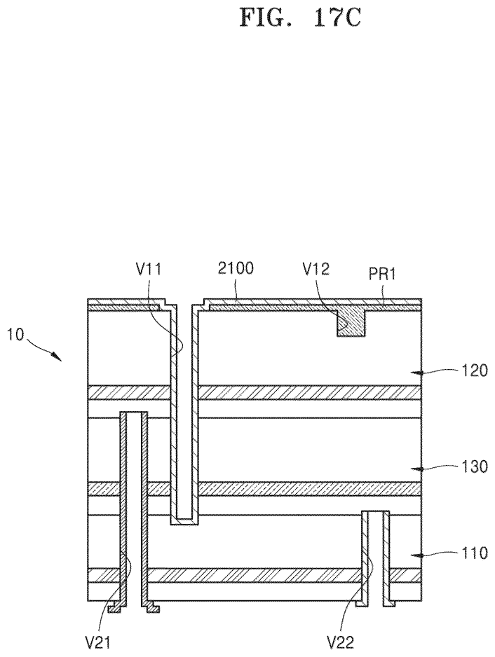

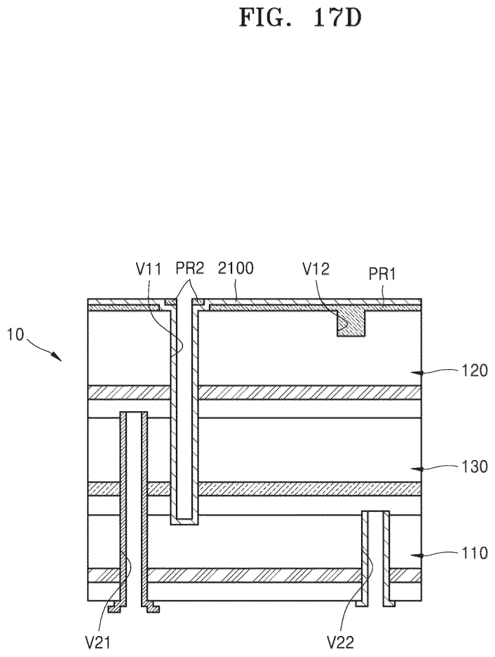

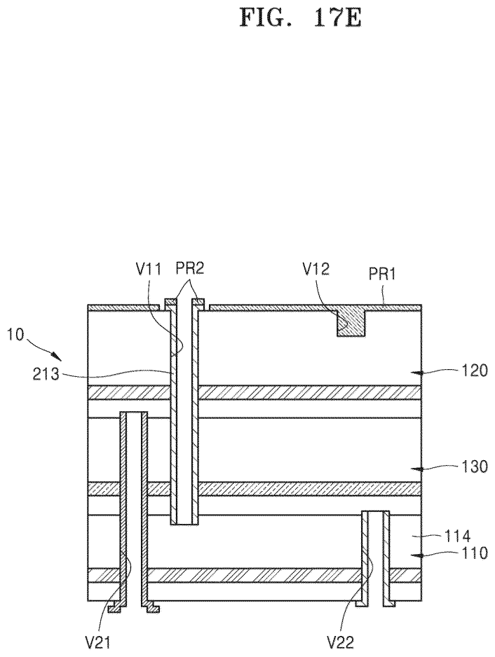

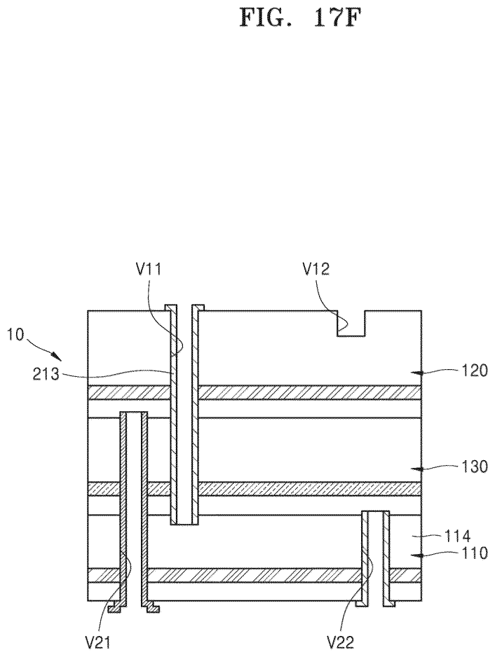

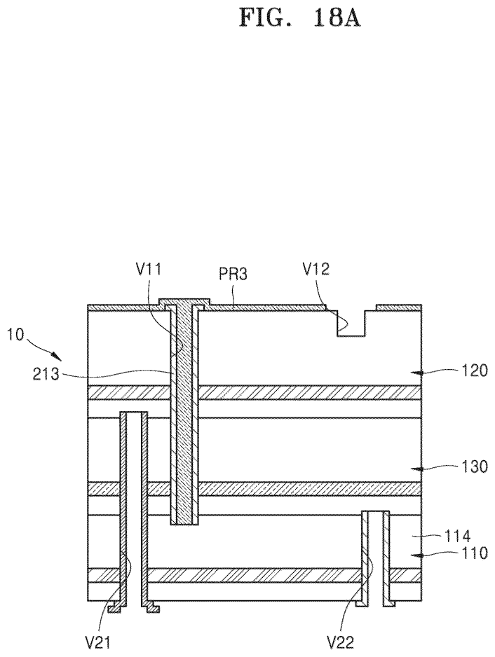

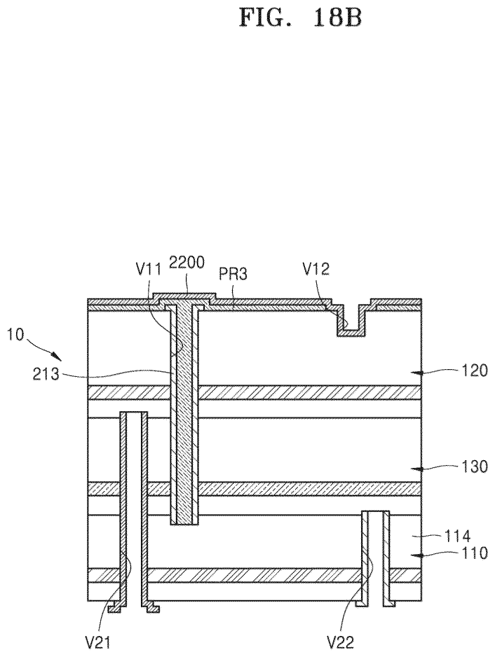

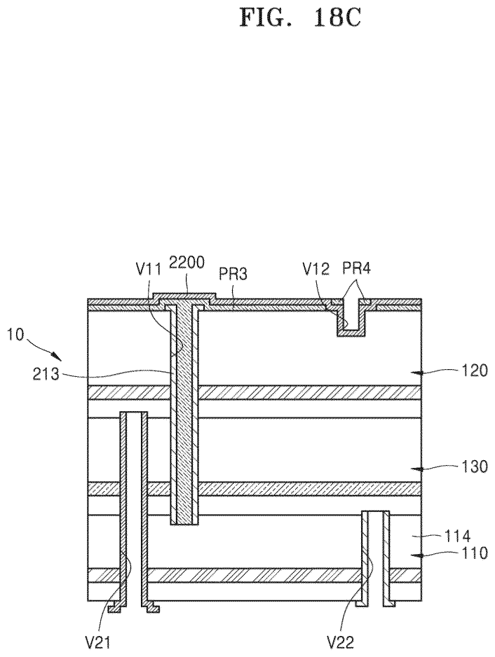

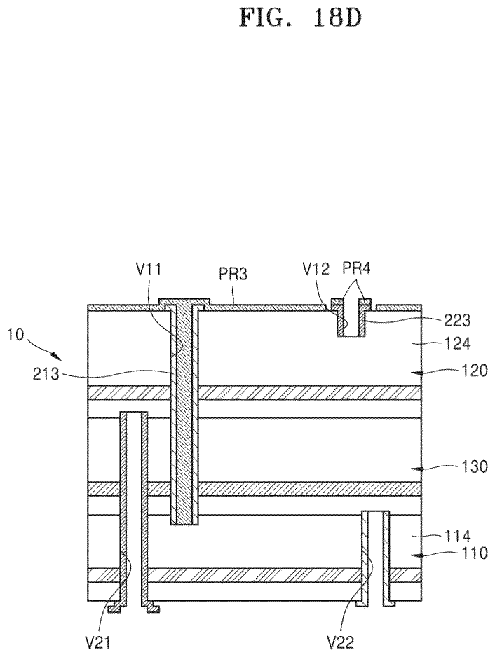

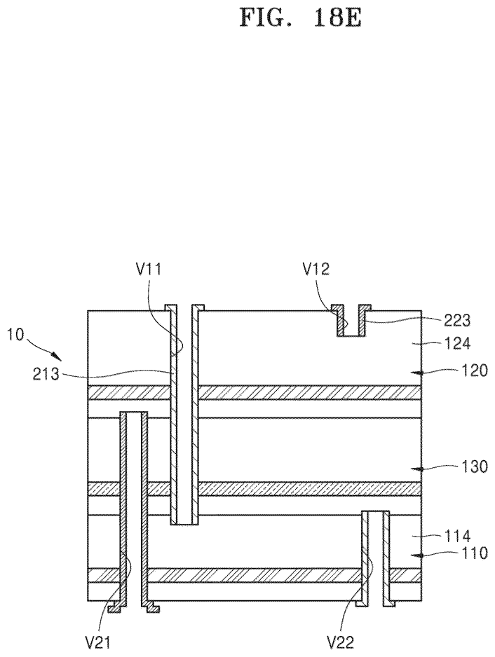

FIG. 16 is a flowchart illustrating a method of manufacturing a micro light-emitting display apparatus according to one or more embodiments. FIGS. 17A to 17F are an operation for explaining an example of an operation of forming the first hole passivation region 213 in the method of manufacturing the micro light-emitting display apparatus according to one or more embodiments. FIGS. 18A to 18E are diagrams for explaining an example of an operation of forming the second hole passivation region 223 in the method of manufacturing the micro light-emitting display apparatus according to one or more embodiments.

Referring to FIG. 16, according to one or more embodiments a first hole passivation region 213 including a first material may be formed (S11).

The first hole passivation region 213 may be partially formed on the light-emitting stack structure 10 in which a plurality of light-emitting elements are stacked. For example, the first hole passivation region 213 may be formed in the first upper via hole V11.

Referring to FIG. 17a, the light-emitting stack structure 10 may be disposed such that the first upper via hole V11 and the second upper via hole V12 face upward.

Referring to FIG. 17B, the first photoresist PR1 may be formed on the light-emitting stack structure 10 to expose a position where the first hole passivation region 213 is to be formed. The first photoresist PR1 may include a photosensitive material. The first photoresist PR1 may be a positive photosensitive material or a negative photosensitive material. The first photoresist PR1 may be formed to have a certain shape by a photolithography process.

The first photoresist PR1 may be formed such that the first upper via hole V11 is exposed and the second upper via hole V12 is filled. The first photoresist PR1 may fill the second upper via hole V12 and may be disposed on a peripheral part of the second upper via hole V12 and a peripheral part of the first upper via hole V11 on an upper surface of the second light-emitting element 120. The first photoresist PR1 may be formed not to be filled in the first upper via hole V11.

Referring to FIG. 17C, the first passivation preparation layer 2100 may be formed on the light-emitting stack structure 10 in which the first photoresist PR1 is formed. The first passivation preparation layer 2100 may include a first material. The first material may include at least one of SiO₂, AlN, AlON, Ta₂O₅, SiN, Al₂O₃, ZrO₂, or HfO₂.

The first passivation preparation layer 2100 may be disposed on the light-emitting stack structure 10 by a deposition process. The first passivation preparation layer 2100 may be formed using a CVD process, a PVD process, or an ALD process.

The first passivation preparation layer 2100 may be disposed along an upper surface of the first photoresist PR1 and an inner surface of the first upper via hole V11.

Referring to FIG. 17D, the second photoresist PR2 may be formed so as not to overlap the first photoresist PR1 in the light-emitting stack structure 10 in which the first passivation preparation layer 2100 is formed. The second photoresist PR2 may include a photosensitive material. The second photoresist PR2 may be a positive photosensitive material or a negative photosensitive material. The second photoresist PR2 may be formed to have a certain shape by a photolithography process. The second photoresist PR2 may be formed to expose a lower surface of the first upper via hole V11.

Referring to FIG. 17E, the first passivation preparation layer 2100 may be patterned to have a certain shape by an etching process. In the etching process, the second photoresist PR2 may function as an etching mask.

A part of the first passivation preparation layer 2100 that is not covered and exposed by the second photoresist PR2 may be removed. A part of the first passivation preparation layer 2100 disposed on the first photoresist PR1 and a part thereof disposed on the lower surface of the first upper via hole V11 may be removed. Accordingly, only a region of the first passivation preparation layer 2100 disposed in a lower portion of the second photoresist PR2 remains.

Referring to FIG. 17F, a photoresist may be removed from the light-emitting stack structure 10 in which the first passivation region 210 is formed. The first photoresist PR1 and the second photoresist PR2 may be removed from the light-emitting stack structure 10. Accordingly, the first hole passivation region 213 partially disposed on the light-emitting stack structure 10 may be formed.

Referring again to FIG. 16, one or more embodiments a second hole passivation region 223 including a second material may be formed (S12). The second hole passivation region 223 may be formed on the light-emitting stack structure 10 to be provided on and cover another region on the same plane as the first hole passivation region 213.

Referring to FIG. 18A, the third photoresist PR3 may be formed on the light-emitting stack structure 10 in which the first hole passivation region 213 is formed. For example, the third photoresist PR3 may be disposed on the upper surface of the first passivation region 210 and may be filled in the first upper via hole V11.

The third photoresist PR3 may include a photosensitive material. The third photoresist PR3 may be a positive photosensitive material or a negative photosensitive material. The third photoresist PR3 may be formed to have a certain shape by a photolithography process.

Referring to FIG. 18B, the second passivation preparation layer 2200 may be formed on the light-emitting stack structure 10 in which the third photoresist PR3 is formed. The second passivation preparation layer 2200 may include a second material. The second material may include at least one of SiO₂, AlN, AlON, Ta₂O₅, SiN, Al₂O₃, ZrO₂, or HfO₂. The second material may be a material different from the first material.

The second passivation preparation layer 2200 may be disposed on the light-emitting stack structure 10 by a deposition process. The second passivation preparation layer 2200 may be formed using a CVD process, a PVD process, or an ALD process.

The second passivation preparation layer 2200 may be deposited on an upper surface of the third photoresist PR3 of the light-emitting stack structure 10 and an inner surface of the second upper via hole V12.

Referring to FIG. 18C, the fourth photoresist PR4 may be formed on a region where the second passivation region 220 is required. The fourth photoresist PR4 may include a photosensitive material. The fourth photoresist PR4 may be a positive photosensitive material or a negative photosensitive material. The fourth photoresist PR4 may be formed to have a certain shape by a photolithography process.

The fourth photoresist PR4 may be disposed not to overlap the first passivation region 210. The fourth photoresist PR4 may not overlap the third photoresist PR3. The fourth photoresist PR4 may expose the lower surface of the first upper via hole V11.

Referring to FIG. 18D, the second passivation preparation layer 2200 may be patterned to have a certain shape by an etching process. In the etching process, the fourth photoresist PR4 may function as an etching mask.

A region of the second passivation preparation layer 2200 that is not covered and exposed by the fourth photoresist PR4 may be removed. A region of the second passivation preparation layer 2200 covered by the fourth photoresist PR4 remains, and a region of the second passivation preparation layer 2200 that is not covered and exposed by the fourth photoresist PR4 may be removed.

The second passivation preparation layer 2200 from which the region not covered and exposed by the fourth photoresist PR4 is removed may be defined as the second hole passivation region 223.

Referring to FIG. 18E, a photoresist may be removed from the light-emitting stack structure 10 in which the first passivation region 210 and the second passivation region 220 are formed. The third photoresist PR3 and the fourth photoresist PR4 may be removed from the light-emitting stack structure 10. Accordingly, the micro light-emitting display apparatus including the passivation layer 20 including the first hole passivation region 213 and the second hole passivation region 223 disposed on the same plane may be manufactured.

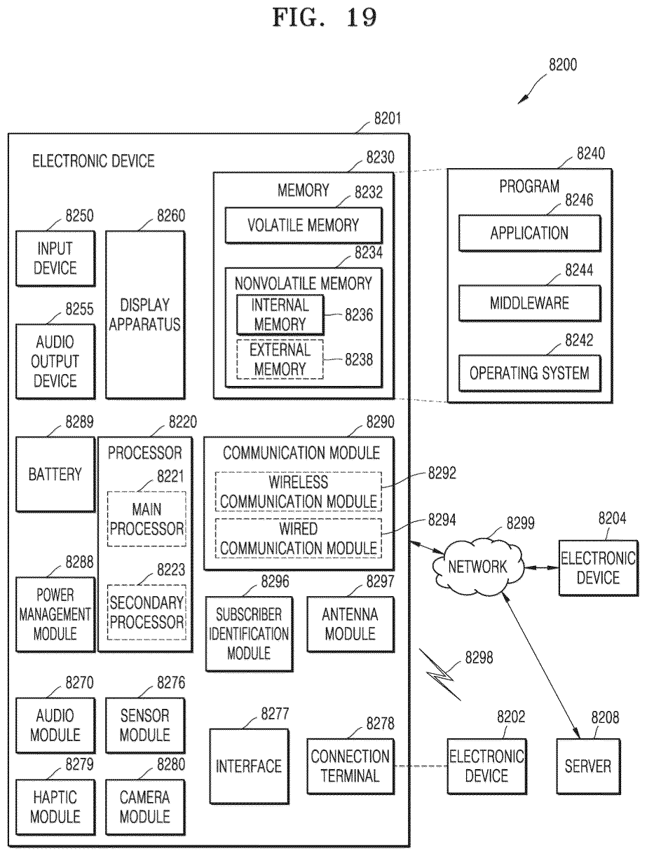

FIG. 19 is a block diagram of an electronic device including a micro light-emitting display apparatus according to one or more embodiments. Referring to FIG. 19, an electronic device 8201 may be provided in a network environment 8200. In the network environment 8200, the electronic device 8201 may communicate with another electronic device 8202 through a first network 8298 (such as a short-range wireless communication network, etc.), or communicate with another electronic device 8204 and/or a server 8208 through a second network 8299 (such as a remote wireless communication network). The electronic device 8201 may communicate with the electronic device 8204 through the server 8208. The electronic device 8201 may include a processor 8220, a memory 8230, an input device 8250, an audio output device 8255, the display apparatus 8260, an audio module 8270, a sensor module 8276, and an interface 8277, a haptic module 8279, a camera module 8280, a power management module 8288, a battery 8289, a communication module 8290, a subscriber identification module 8296, and/or an antenna module 8297. In the electronic device 8201, some of these components may be omitted or other components may be added. Some of these components may be implemented as one integrated circuit. For example, the sensor module 8276 (fingerprint sensor, iris sensor, illuminance sensor, etc.) may be implemented by being embedded in the display apparatus 8260 (display, etc.).

The processor 8220 may execute software (the program 8240, etc.) to control one or a plurality of other components (such as hardware, software components, etc.) of the electronic device 8201 connected to the processor 8220, and perform various data processing or operations. For example, the processor 8220 may control the display apparatus 8260. As part of data processing or operation, the processor 8220 may load commands and/or data received from other components (the sensor module 8276, the communication module 8290, etc.) into a volatile memory 8232, process commands and/or data stored in the volatile memory 8232, and store result data in a nonvolatile memory 8234. The nonvolatile memory 8234 may include an internal memory 8236 and an external memory 8238. The processor 8220 may include a main processor 8221 (such as a central processing unit, an application processor, etc.) and a secondary processor 8223 (such as a graphics processing unit, an image signal processor, a sensor hub processor, a communication processor, etc.) that may be operated independently or together. The secondary processor 8223 may use less power than the main processor 8221 and may perform specialized functions.

The secondary processor 8223 may control functions and/or states related to some of the components of the electronic device 8202 (such as the display apparatus 8260, the sensor module 8276, the communication module 8290, etc.) instead of the main processor 8221 while the main processor 8221 is in an inactive state (sleep state), or with the main processor 8221 while the main processor 8221 is in an active state (application execution state). The secondary processor 8223 (such as an image signal processor, a communication processor, etc.) may be implemented as part of other functionally related components (such as the camera module 8280, the communication module 8290, etc.)

The memory 8230 may store various data required by components of the electronic device 8201 (such as the processor 8220, the sensor module 8276, etc.). The data may include, for example, software (such as the program 8240, etc.) and input data and/or output data for commands related thereto. The memory 8230 may include the volatile memory 8232 and/or the nonvolatile memory 8234.

The program 8240 may be stored as software in the memory 8230 and may include an operating system 8242, a middleware 8244, and/or an application 8246.

The input device 8250 may receive commands and/or data to be used for components (such as the processor 8220, etc.) of the electronic device 8201 from outside (a user) of the electronic device 8201. The input device 8250 may include a remote controller, a microphone, a mouse, a keyboard, and/or a digital pen (such as a stylus pen).

The audio output device 8255 may output an audio signal to the outside of the electronic device 8201. The audio output device 8255 may include a speaker and/or a receiver. The speaker may be used for general purposes such as multimedia playback or recording playback, and the receiver may be used to receive incoming calls. The receiver may be combined as a part of the speaker or may be implemented as an independent separate device.

The display apparatus 8260 may be the micro light-emitting display apparatus 8260 according to the embodiments described above. The display apparatus 8260 may visually provide information to the outside of the electronic device 8201. The display apparatus 8260 may include the display, a hologram device, or a projector and a control circuit for controlling the device. The display apparatus 8260 may include the display apparatus according to one or more embodiments. The display apparatus 8260 may include a touch circuit set to sense a touch, and/or a sensor circuit (such as a pressure sensor) set to measure the strength of a force generated by the touch.

The audio module 8270 may convert sound into an electrical signal, or conversely, may convert an electrical signal into sound. The audio module 8270 may acquire sound through the input device 8250 or output sound through speakers and/or headphones of the audio output device 8255, and/or another electronic device (such as the electronic device 8102) directly or wirelessly connected to electronic device 8201.

The sensor module 8276 may detect an operating state (such as power, temperature, etc.) of the electronic device 8201 or an external environmental state (such as a user state, etc.), and generate an electrical signal and/or data value corresponding to the detected state. The sensor module 8276 may include a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The interface 8277 may support one or more specified protocols that may be used for the electronic device 8201 to connect directly or wirelessly with another electronic device (such as the electronic device 8102). The interface 8277 may include a High Definition Multimedia Interface (HDMI), a Universal Serial Bus (USB) interface, an SD card interface, and/or an audio interface.

The connection terminal 8278 may include a connector through which the electronic device 8201 may be physically connected to another electronic device (such as the electronic device 8102). The connection terminal 8278 may include an HDMI connector, a USB connector, an SD card connector, and/or an audio connector (such as a headphone connector).

The haptic module 8279 may convert an electrical signal into a mechanical stimulus (such as vibration, movement, etc.) or an electrical stimulus that a user may perceive through a tactile or motor sense. The haptic module 8279 may include a motor, a piezoelectric element, and/or an electrical stimulation device.

The camera module 8280 may capture a still image and a video. The camera module 8280 may include a lens assembly including one or more lenses, image sensors, image signal processors, and/or flashes. The lens assembly included in the camera module 8280 may collect light emitted from a subject that is a target of image capturing.

The power management module 8288 may manage power supplied to the electronic device 8201. The power management module 8388 may be implemented as a part of a Power Management Integrated Circuit (PMIC).

The battery 8289 may supply power to components of the electronic device 8201. The battery 8289 may include a non-rechargeable primary cell, a rechargeable secondary cell, and/or a fuel cell.

The communication module 8290 may support establishing a direct (wired) communication channel and/or a wireless communication channel, and performing communication through the established communication channel between the electronic device 8201 and other electronic devices (such as the electronic device 8102, the electronic device 8104, the server 8108, etc.) The communication module 8290 may include one or more communication processors that operate independently of the processor 8220 (such as an application processor) and support direct communication and/or wireless communication. The communication module 8290 may include a wireless communication module 8292 (such as a cellular communication module, a short-range wireless communication module, a Global Navigation Satellite System (GNSS) communication module, and the like) and/or a wired communication module 8294 (such as a local area network (LAN) communication module, a power line communication module, etc.) Among these communication modules, a corresponding communication module may communicate with other electronic devices through a first network 8298 (a short-range communication network such as Bluetooth, WiFi Direct, or Infrared Data Association (IrDA)) or a second network 8299 (a cellular network, the Internet, or a telecommunication network such as a computer network (such as LAN, WAN, etc.)) These various types of communication modules may be integrated into one component (such as a single chip, and the like), or may be implemented as a plurality of separate components (a plurality of chips). The wireless communication module 8292 may check and authenticate the electronic device 8201 in a communication network such as the first network 8298 and/or the second network 8299 using the subscriber information (such as international mobile subscriber identifier (IMSI), etc.) stored in the subscriber identification module 8296.

The antenna module 8297 may transmit signals and/or power to the outside (such as other electronic devices) or receive signals and/or power from the outside. The antenna may include a radiator made of a conductive pattern formed on a substrate (such as PCB, etc.) The antenna module 8297 may include one or a plurality of antennas. When multiple antennas are included, an antenna suitable for a communication method used in a communication network such as the first network 8298 and/or the second network 8299 may be selected from the plurality of antennas by the communication module 8290. Signals and/or power may be transmitted or received between the communication module 8290 and another electronic device through the selected antenna. In addition to the antenna, other components (such as RFIC) may be included as part of the antenna module 8297.

Some of the components are connected to each other and may exchange signals (such as commands, data, etc.) through communication method between peripheral devices (such as bus, General Purpose Input and Output (GPIO), Serial Peripheral Interface (SPI), Mobile Industry Processor Interface (MIPI), etc.)

The command or data may be transmitted or received between the electronic device 8201 and the external electronic device 8204 through the server 8108 connected to the second network 8299. The other electronic devices 8202 and 8204 may be the same or different types of devices as or from the electronic device 8201. All or some of the operations executed by the electronic device 8201 may be executed by one or more of the other electronic devices 8202, 8204, and 8208. For example, when the electronic device 8201 needs to perform a certain function or service, instead of executing the function or service itself, the electronic device 8201 may request one or more other electronic devices to perform the function or part or all of the service. One or more other electronic devices that receive the request may execute an additional function or service related to the request, and transmit a result of the execution to the electronic device 8201. To this end, cloud computing, distributed computing, and/or client-server computing technology may be used.

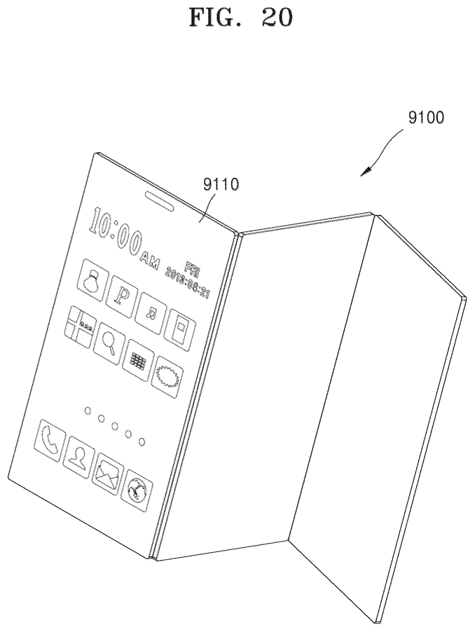

FIG. 20 is a diagram illustrating an example in which a display apparatus according to one or more embodiments is applied to a mobile device. A mobile device 9100 may include a display apparatus 9110. The display apparatus 9110 may include a micro light-emitting display apparatus according to one or more embodiments. The display apparatus 9110 may have a foldable structure, for example, a multi-foldable structure.

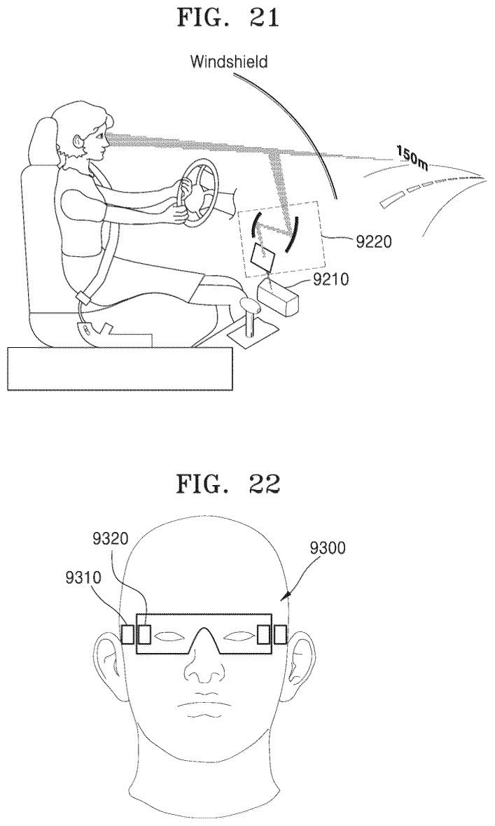

FIG. 21 is a diagram illustrating an example in which a display apparatus according to one or more embodiments is applied to a vehicle. The display apparatus may be a vehicle head-up display apparatus 9200, and may include a display 9210 provided in an area of a vehicle, and a light path changing member 9220 that converts an optical path so that a driver may see the image generated on the display 9210.

FIG. 22 is a diagram illustrating an example in which a display apparatus according to one or more embodiments is applied to augmented reality glasses or virtual reality glasses. Augmented reality glasses 9300 may include a projection system 9310 that forms an image, and an element 9320 that guides the image from the projection system 9310 into the user's eye. The projection system 9310 may include the display apparatus according to one or more embodiments.

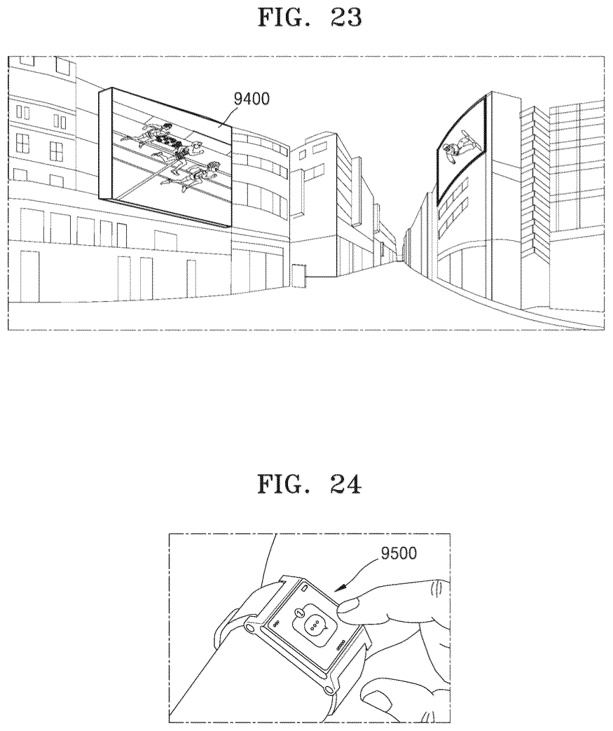

FIG. 23 is a diagram illustrating an example in which a display apparatus according to one or more embodiments is applied to signage. The signage 9400 may be used for outdoor advertisement using a digital information display, and may control advertisement contents and the like through a communication network. The signage 9400 may be implemented, for example, through the electronic device described with reference to FIG. 19.

FIG. 24 is a diagram illustrating an example in which a display apparatus according to one or more embodiments is applied to a wearable display. A wearable display 9500 may include the display apparatus according to one or more embodiments, and may be implemented through the electronic device described with reference to FIG. 19.

The light-emitting device according to the embodiment or the display apparatus including the light-emitting device may also be applied to various products such as a rollable TV and a stretchable display.

One or more embodiments may implement the micro light-emitting display apparatus having improved light emission efficiency through a passivation layer including passivation regions including different materials and the method of manufacturing the micro light-emitting display apparatus.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. A micro light-emitting display apparatus comprising:
a light-emitting stack structure configured to emit light through an upper surface of the light-emitting stack structure, the light-emitting stack structure comprising a first light-emitting element configured to emit light of a first wavelength and a second light-emitting element configured to emit light of a second wavelength; and
a passivation layer on at least the upper surface of the light-emitting stack structure,
wherein the passivation layer comprises:
a first passivation region comprising a first material configured to transmit the light of the first wavelength external to the micro light-emitting display apparatus; and
a second passivation region comprising a second material, different from the first material, configured to transmit the light of the second wavelength external to the micro light-emitting display apparatus, the second passivation region being on a same plane as the first passivation region.

2. The micro light-emitting display apparatus of claim 1, wherein the first passivation region comprises a first upper passivation region on a first partial region of the upper surface of the light-emitting stack structure, and
wherein the second passivation region comprises a second upper passivation region on a second partial region of the upper surface of the light-emitting stack structure.

3. The micro light-emitting display apparatus of claim 2, wherein an end portion of a boundary part of the first upper passivation region and an end portion of a boundary part of the second upper passivation region opposite to each other contact each other.

4. The micro light-emitting display apparatus of claim 3, wherein a thickness of the boundary part of the first upper passivation region is greater than thicknesses of parts of the first upper passivation region other than the boundary part of the first upper passivation region and the second upper passivation region.

5. The micro light-emitting display apparatus of claim 2, wherein an end portion of the first upper passivation region and an end portion of the second upper passivation region opposite to each other are spaced apart from each other.

6. The micro light-emitting display apparatus of claim 5, wherein a gap between the first upper passivation region and the second upper passivation region corresponds to a thickness of the first upper passivation region or a thickness of the second upper passivation regions.

7. The micro light-emitting display apparatus of claim 1, wherein the first passivation region comprises a first side passivation region on a first partial region of a side surface of the light-emitting stack structure, and
wherein the second passivation region comprises a second side passivation region on a second partial region of the side surface of the light-emitting stack structure.

8. The micro light-emitting display apparatus of claim 7, wherein the first side passivation region is on a side surface of the first light-emitting element, and
wherein the second side passivation region is on a side surface of the second light-emitting element.

9. The micro light-emitting display apparatus of claim 1, wherein the light-emitting stack structure further comprises:
a first upper via hole extending downward from the upper surface of the light-emitting stack structure such that a first upper electrode is electrically connected to the first light-emitting element; and
a second upper via hole extending downward from the upper surface of the light-emitting stack structure such that a second upper electrode is electrically connected to the second light-emitting element.

10. The micro light-emitting display apparatus of claim 9, wherein the first passivation region comprises a first hole passivation region between an inner surface of the first upper via hole and the first upper electrode, and
wherein the second passivation region comprises a second hole passivation region between an inner surface of the second upper via hole and the second upper electrode.

11. The micro light-emitting display apparatus of claim 1, wherein the light of the first wavelength comprises a red light wavelength, and
wherein the first material comprises at least one of SiO₂, AlN, AlON, Ta₂O₅, SiN, Al₂O₃, ZrO₂, or HfO₂.

12. The micro light-emitting display apparatus of claim 11, wherein the light of the second wavelength comprises a blue light wavelength, and
wherein the second material comprises at least one of SiO₂, AlN, AlON, Ta₂O₅, SiN, Al₂O₃, ZrO₂, or HfO₂.

13. The micro light-emitting display apparatus of claim 1, wherein the light-emitting stack structure further comprises a third light-emitting element between the first light-emitting element and the second light-emitting element, the third light-emitting element being configured to emit light of a third wavelength different from the first wavelength and the second wavelength.

14. The micro light-emitting display apparatus of claim 13, wherein the passivation layer further comprises a third passivation region comprising a third material different from the first material and the second material and configured to transmit the light of the third wavelength external to the micro light-emitting display apparatus, and
wherein the third passivation region is on the same plane as the first passivation region and the second passivation region.

15. An electronic device comprising:
a micro light-emitting display apparatus; and
at least one processor configured to control the micro light-emitting display apparatus,
wherein the micro light-emitting display apparatus comprises:
a light-emitting stack structure configured to emit light through an upper surface of the light-emitting stack structure, the light-emitting stack structure comprising a first light-emitting element configured to emit light of a first wavelength and a second light-emitting element configured to emit light of a second wavelength; and
a passivation layer on at least the upper surface of the light-emitting stack structure,
wherein the passivation layer comprises:
a first passivation region comprising a first material configured to transmit the light of the first wavelength external to the micro light-emitting display apparatus; and
a second passivation region comprising a second material, different from the first material, configured to transmit the light of the second wavelength external to the micro light-emitting display apparatus, the second passivation region being on a same plane as the first passivation region.

16. A method of manufacturing a micro light-emitting display apparatus, the method comprising:
partially forming a first passivation region on a first region of a light-emitting stack structure that comprises a first light-emitting element and a second light-emitting element; and
forming a second passivation region on a second region of the light-emitting stack structure and on a same plane as the first passivation region, a material of the second passivation region being different from a material of the first passivation region.

17. The method of claim 16, wherein the forming of the first passivation region comprises forming the first passivation region on a first partial region of an upper surface of the light-emitting stack structure, and
wherein the forming of the second passivation region comprises forming the second passivation region on a second partial region of the upper surface of the light-emitting stack structure.

18. The method of claim 17, wherein the forming of the first passivation region comprises forming the first passivation region on a first partial region of a side surface of the light-emitting stack structure, and
wherein the forming of the second passivation region comprises forming the second passivation region on a second partial region of the side surface of the light-emitting stack structure.

19. The method of claim 16, wherein the second passivation region is adjacent to the first passivation region on an upper surface of the light-emitting stack structure.

20. The method of claim 16, wherein a first material of the first passivation region comprises at least one of SiO₂, AlN, AlON, Ta₂O₅, SiN, Al₂O₃, ZrO₂, or HfO₂, and
wherein a second material of the second passivation region comprises at least one of SiO₂, AlN, AlON, Ta₂O₅, SiN, Al₂O₃, ZrO₂, or HfO₂.
